(19) United States
(12) Patent Application Publication
(10) Pub. No.: US 2026/0223344 A1
(43) Pub. Date: Jul. 30, 2026

(54) FEEDER STORAGE SYSTEM

(71) Applicant: FUJI CORPORATION, Chiryu (JP)

(72) Inventors: Masataka IWASAKI, Anjo-shi (JP); Daisuke KATO, Kuwana-shi (JP)

(73) Assignee: FUJI CORPORATION, Chiryu (JP)

(21) Appl. No.: 19/150,827

(22) PCT Filed: Jan. 25, 2023
(86) PCT No.: PCT/JP2023/002190

§ 371 Date: Jul. 24, 2025

(51) Int. Cl. H05K 13/04; H05K 13/00; H05K 13/02

(52) U.S. Cl. CPC H05K 13/0419; H05K 13/0084; H05K 13/021

(57) ABSTRACT

A feeder storage system includes a storage configured to store a tape feeder that is detachably mounted on a component mounter and supplies a component; a feeder maintenance device disposed adjacent to the storage and configured to perform maintenance of the tape feeder; and a conveyance device configured to move along an arrangement direction of the storage and the feeder maintenance device and convey the tape feeder between the storage and the feeder maintenance device.

### TECHNICAL FIELD

The present description relates to a feeder storage system that stores a tape feeder detachably mounted on a component mounter.

### BACKGROUND ART

A technique for mass-producing board products by performing board work on a board on which a circuit pattern is formed is widespread. As a representative example of a board work machine, there is a component mounter for mounting a component on a board. Many component mounters are detachably equipped with a tape feeder that supplies components using a carrier tape. In general, a large number of tape feeders are prepared, the number being larger than a quantity of the tape feeders to be mounted on the component mounter, and are conveyed by a worker from a storage warehouse or a setup area to the component mounter. In addition, since the tape feeder includes a movable portion such as a feeding mechanism of the carrier tape, maintenance is required. Technical examples related to storage, conveyance, and maintenance for this type of tape feeder are disclosed in Patent Literatures 1 and 2.

A component mounting system disclosed in Patent Literature 1 includes a component mounting device, a component storage section configured to store a tape feeder, and a self-propelled component replenishing device configured to move the tape feeder from the component storage section to the component mounting device. According to this, it is assumed that it is possible to reduce work of the worker related to a component exchange operation.

In addition, a feeder maintenance device disclosed in Patent Literature 2 includes a slot to which a tape feeder that performs a feeding operation of a carrier tape by means of a sprocket to supply a component is attached, an ejection unit for ejecting air toward the sprocket, and a control unit for causing the ejection unit to eject air while causing the sprocket to rotate. According to this, it is assumed that it is possible to easily and sufficiently clean the sprocket.

### CITATION LIST

### Patent Literature

Patent Literature 1: JP-A-2021-182626
Patent Literature 2: JP-A-2014-220317

### BRIEF SUMMARY

### Technical Problem

Meanwhile, in the technical example of Patent Literature 1, since the self-propelled component replenishing device conveys the tape feeder from the component storage section to the component mounting device, conveyance work is made more labor-saving, which is preferable. Further, in the technical example of Patent Literature 2, it is possible to save labor in maintenance work of the tape feeder conventionally performed by the worker, which is preferable. However, when maintenance of the tape feeder is performed using a configuration in which the technical examples of Patent Literatures 1 and 2 are combined, the worker needs to perform work of extracting the tape feeder from the component storage section, conveying the tape feeder to the feeder maintenance device, and inserting the tape feeder into the device. Further, the worker needs to perform work of moving the tape feeder for which the maintenance has been ended in a direction opposite to the above. Therefore, it cannot be said that sufficient labor saving is achieved.

Therefore, in the present description, an object is to provide a feeder storage system capable of saving labor in work related to storage, conveyance, and maintenance of a tape feeder as compared with the conventional art.

### Solution to Problem

The present description discloses a feeder storage system including: a storage configured to store a tape feeder that is detachably mounted on a component mounter and supplies a component; a feeder maintenance device disposed adjacent to the storage and configured to perform maintenance of the tape feeder; and a conveyance device configured to move along an arrangement direction of the storage and the feeder maintenance device and convey the tape feeder between the storage and the feeder maintenance device.

### Advantageous Effects

In the disclosed feeder storage system, the conveyance device conveys the tape feeder between the storage and the feeder maintenance device. According to this, it is possible to save labor in work of conveying the tape feeder between the storage and the feeder maintenance device and work of taking the tape feeder in and out of the storage or the feeder maintenance device as compared with the conventional art.

### BRIEF DESCRIPTION OF DRAWINGS

FIG. 1 is a plan view showing an overall configuration example of a component mounter in which a tape feeder is detachably mounted.

FIG. 2 is a side view of the tape feeder.

FIG. 3 is a perspective view showing a suction nozzle as one form of a component mounting tool.

FIG. 4 is a perspective view of a nozzle feeder (mounting tool feeder) which is detachably mounted on the component mounter and supplies the suction nozzle (component mounting tool).

FIG. 5 is a perspective view schematically showing an overall configuration of a feeder storage system of an embodiment.

FIG. 6 is a diagram showing an appearance and functional blocks of a feeder maintenance device.

FIG. 7 is a perspective view schematically showing an internal configuration of a reel attachment/detachment device.

FIG. 8 is a diagram showing an appearance and functional blocks of a nozzle operation device (mounting tool operation device).

FIG. 9 is a perspective view of a reel conveyance vehicle (second conveyance device) that collectively conveys multiple reels.

FIG. 10 is a perspective view of a magazine conveyance vehicle (third conveyance device) that conveys a feeder magazine.

FIG. 11 is a functional block diagram showing an overall configuration related to control of the feeder storage system.

FIG. 12 is a diagram of an operation flow illustrating an operation of the feeder storage system when a changeover command is received.

FIG. 13 is a diagram of an operation flow illustrating an operation of the feeder storage system when a retrieval command is received.

### DESCRIPTION OF EMBODIMENTS

### 1. Overall Configuration Example of Component Mounter 9

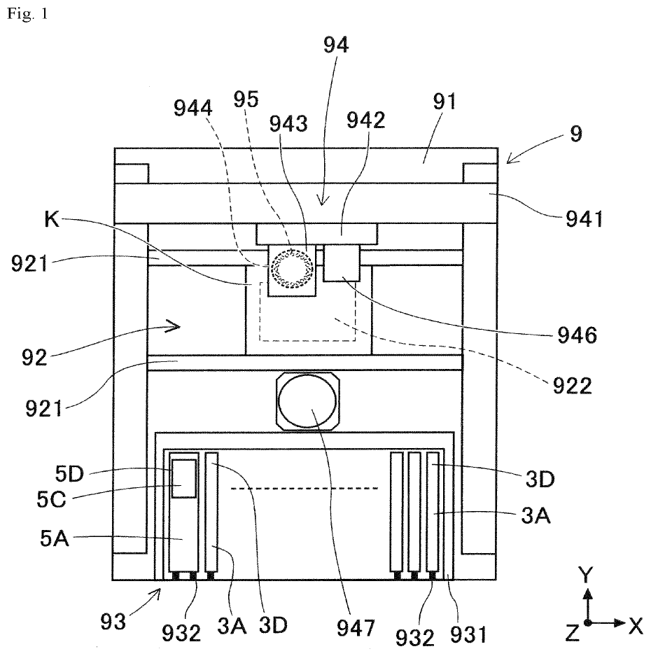

Feeder storage system 1 of an embodiment stores tape feeder 3A and nozzle feeder 5A which are detachably mounted on component mounter 9. First, configurations of component mounter 9, tape feeder 3A, suction nozzle 95, and nozzle feeder 5A will be described with reference to FIGS. 1 to 4. Component mounter 9 shown in FIG. 1 performs mounting work of mounting a component on board K. A horizontal direction from a left side toward a right side on a drawing surface in FIG. 1 is an X-axis direction in which board K is conveyed, a horizontal direction from a lower side (front side) toward an upper side (rear side) on the drawing surface is a Y-axis direction, and a vertical direction is a Z-axis direction. Component mounter 9 is configured by assembling board conveyance device 92, component supply device 93, component transfer device 94, a control device (not shown), and the like to base 91.

Board conveyance device 92 includes pair of guide rails 921, a pair of conveyance belts (not shown), clamp mechanism 922, and the like. Pair of guide rails 921 extends in the X-axis direction across the center of an upper surface of base 91, and guide rails 921 are assembled to base 91 in parallel to each other. The pair of conveyance belts rotates along guide rails 921 in a state where two parallel sides of board K are placed thereon, and conveys board K to a stop position in vicinity of the center of base 91. Clamp mechanism 922 is disposed below the stop position and pushes up board K to clamp and position board K between guide rails 921 and clamp mechanism 922. After the mounting work of the component performed by component transfer device 94 is ended, clamp mechanism 922 releases board K, and the conveyance belts unload board K to an outside of the device.

Component supply device 93 is disposed at a front portion of the upper surface of base 91 in the Y-axis direction. Component supply device 93 includes pallet table 931 and multiple tape feeders 3A. Pallet table 931 has a substantially rectangular shape in a plan view, and includes multiple slots 932 extending in parallel with each other in the Y-axis direction while being separated from each other. Each of multiple tape feeders 3A is detachably inserted into and mounted on slot 932. Further, nozzle feeder 5A is inserted into and mounted on slot 932.

Component transfer device 94 includes Y-axis moving body 941, X-axis moving body 942, mounting head 943, nozzle tool 944, multiple suction nozzles 95 (component mounting tools), board camera 946, part camera 947, and the like. Y-axis moving body 941 and X-axis moving body 942 constitute an X-Y drive mechanism that moves mounting head 943 in two horizontal directions. Nozzle tool 944 as a rotationally symmetric body is provided on a lower side of mounting head 943. Nozzle tool 944 is provided with multiple (20 in the example of FIG. 1) suction nozzles 95 in an automatically exchangeable manner. Suction nozzle 95 performs mounting work of picking up the component from component supply device 93 and mounting the component on board K at the stop position. In mounting head 943, multiple suction nozzles 95 may be provided side by side in a row or may be provided to be arranged in a lattice shape. In addition, a component mounting tool other than suction nozzle 95, for example, a chuck-type mounting tool for gripping the component may be provided in mounting head 943 in an automatically exchangeable manner.

Board camera 946 is provided downward on X-axis moving body 942 adjacent to mounting head 943. Board camera 946 images a position mark attached to board K from above to accurately obtain the stop position of board K. Part camera 947 is provided upward between board conveyance device 92 and component supply device 93. Part camera 947 images the component held by suction nozzle 95 from below and recognizes the component while mounting head 943 moves from component supply device 93 to board K. As a result, it is determined whether a type of the component is correct or incorrect, and a position and an orientation of the component with respect to suction nozzle 95 are detected and applied in the mounting work. Examples of board camera 946 and part camera 947 include a digital imaging device including an imaging element such as a charge-coupled device (CCD) or a complementary metal-oxide semiconductor (CMOS).

The control device (not shown) is assembled to base 91, and a position thereof is not particularly limited. The control device is configured using a computer device. The control device may be configured such that multiple CPUs are distributed and disposed in the device and communicably connected to each other. The control device controls board conveyance device 92, component supply device 93, and component transfer device 94 based on mounting work data created for each type of a board product (board K), and advances the mounting work for the component.

### 2. Configuration of Tape Feeder 3A

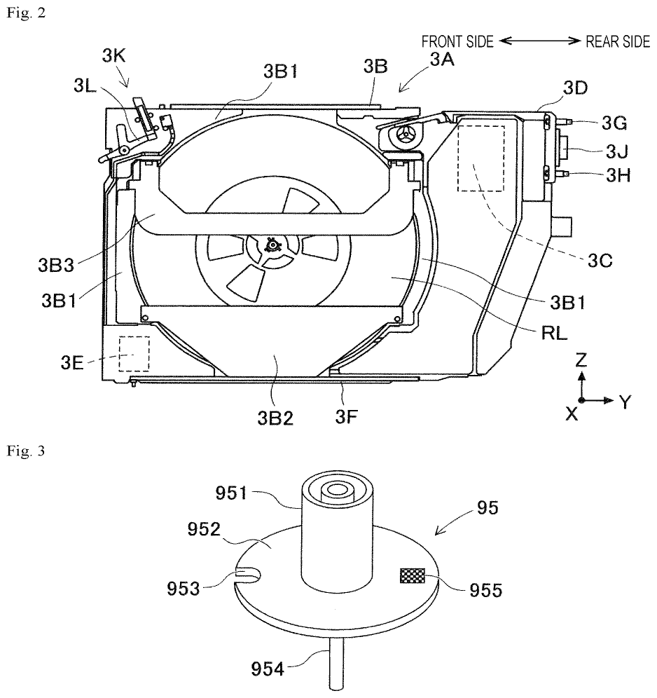

Tape feeder 3A shown in FIG. 2 feeds a carrier tape wound around reel RL by a predetermined pitch and supplies the component at supply position 3D. The carrier tape includes a base tape provided with multiple cavity portions for accommodating components and a cover tape peelably bonded to the base tape to cover the cavity portions. Tape feeder 3A is formed to be thin in a width direction (X-axis direction) by assembling various members to frame body 3B including a side plate. Tape feeder 3A includes frame body 3B, tape feeding mechanism 3C, supply position 3D, feeder control section 3E, protrusion 3F, upper positioning pin 3G, lower positioning pin 3H, connector 3J, lock mechanism 3K, and the like.

Frame body 3B includes reel accommodation frame 3B1, accommodation plate 3B2, and accommodation plate 3B3. Reel accommodation frame 3B1 is multiple members that form a large circular internal space substantially at the center of frame body 3B. Reel accommodation frame 3B1 rotatably accommodates reel RL in the internal space. Accommodation plate 3B2 is openably and closably attached toward a lower portion of reel accommodation frame 3B1, and accommodation plate 3B3 is openably and closably attached toward an upper portion of reel accommodation frame 3B1. Accommodation plate 3B2 and accommodation plate 3B3 enable exchange of reel RL in an open state, and prevent detachment of reel RL accommodated in a closed state.

Tape feeding mechanism 3C is provided at an upper rear portion of frame body 3B. Tape feeding mechanism 3C pulls out the carrier tape from reel RL and feeds the carrier tape toward supply position 3D provided at a rear portion of an upper surface of frame body 3B. Tape feeding mechanism 3C includes, for example, a sprocket that is fitted into a feed hole provided in the carrier tape and rotates, a drive source that generates a driving force, a transmission mechanism that transmits the driving force to the sprocket, and a tape detection section that detects presence or absence of the carrier tape. Feeder control section 3E is disposed in a front lower portion of frame body 3B. Feeder control section 3E is communicably connected to the control device of component mounter 9 via connector 3J. The control device acquires individual identification information and various unique information of tape feeder 3A via communication with feeder control section 3E. Feeder control section 3E may store individual identification information and various unique information of reel RL held in tape feeder 3A. In this case, the control device may simultaneously acquire information of reel RL via the communication with feeder control section 3E. Meanwhile, feeder control section 3E controls tape feeding mechanism 3C according to a command from the control device, and monitors a state of lock mechanism 3K.

Protrusion 3F is provided to protrude downward from a bottom surface of frame body 3B, and is inserted into slot 932 of pallet table 931. Accordingly, tape feeder 3A is attached. Upper positioning pin 3G and lower positioning pin 3H are separately provided on a rear surface of frame body 3B, and are fitted into positioning holes (not shown) of pallet table 931 to position tape feeder 3A. Connector 3J is provided between upper positioning pin 3G and lower positioning pin 3H, and performs power supply and communication connection from a main body of component mounter 9 to tape feeder 3A. When tape feeder 3A is positioned, connector 3J is automatically fitted in a receiving connector (not shown) of pallet table 931. Lock mechanism 3K is provided on a front upper portion of frame body 3B. Lock mechanism 3K is configured using lock member 3L that has a substantially F shape and swings. Lock mechanism 3K restricts and releases an attachment/detachment operation of tape feeder 3A to and from pallet table 931.

### 3. Configuration of Suction Nozzle 95

As shown in FIG. 3, suction nozzle 95 includes body shaft 951, flange 952, nozzle shaft 954, and identification code 955. Body shaft 951 is formed in a cylindrical shape, and an inside thereof serves as an air flow path. Flange 952 is formed in a circular plate shape having a diameter larger than that of body shaft 951, and is coupled to one end side (a lower side in FIG. 3) in an axial direction of body shaft 951. Notch 953 that is recessed toward a center side is formed in a part of an outer peripheral edge of flange 952. Notch 953 is for fixing a rotation angle around the axis when suction nozzle 95 is held by nozzle tool 944, or for measuring the rotation angle.

Nozzle shaft 954 is formed in a circular tube shape extending in the axial direction from body shaft 951, and an inside thereof is an air flow path. Negative pressure air is supplied to the air flow path of nozzle shaft 954, and an opening of a distal end portion of nozzle shaft 954 comes into contact with the component and picks up the component. Nozzle shaft 954 is configured to advance and retreat in the axial direction with respect to body shaft 951 via an expansion and contraction portion (not illustrated) configured using an elastic member such as a coil spring. Nozzle shaft 954 is biased by an elastic member in a direction advancing from body shaft 951. When a load toward body shaft 951 is applied to the distal end portion, nozzle shaft 954 retreats to the inside of body shaft 951 against an elastic force of the elastic member. This reduces a shock and a load value acting on the component from suction nozzle 95 during a pickup operation and during a mounting process. Identification code 955 is attached to an upper surface of flange 952. Identification code 955 includes, for example, a two-dimensional code, and includes unique information such as a type and individual information of suction nozzle 95.

### 4. Configuration of Nozzle Feeder 5A

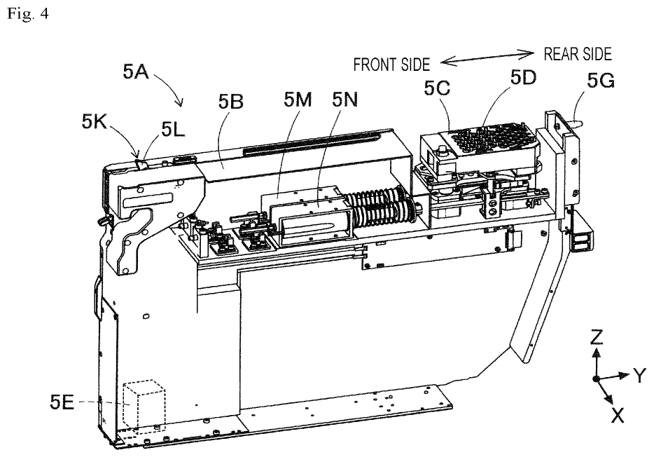

Next, a configuration of nozzle feeder 5A will be described with reference to FIG. 4. Nozzle feeder 5A is one form of the mounting tool feeder that is detachably mounted on component mounter 9 and exchangeably holds the component mounting tool (suction nozzle 95). The mounting tool feeder is not limited thereto, and may exchangeably hold a chuck-type mounting tool. Nozzle feeder 5A has substantially the same outer shape as tape feeder 3A except for a width dimension in the X-axis direction, and has compatibility with tape feeder 3A in terms of a mounting position. Nozzle feeder 5A has substantially the same width dimension as tape feeder 3A, or has a width dimension larger than that of tape feeder 3A (about twice the width dimension in the example of FIG. 1), and is detachably attached to one or multiple slots 932 of pallet table 931.

As shown in FIG. 4, nozzle feeder 5A is formed to be thin in the width direction (X-axis direction) by assembling various members to frame body 5B including a side plate. Nozzle feeder 5A includes frame body 5B, nozzle station 5C, lifting and lowering drive section 5M, restriction drive section 5N, exchange position 5D, nozzle feeder control section 5E, a protrusion, upper positioning pin 5G, a lower positioning pin, a connector, lock mechanism 5K using lock member 5L, and the like.

Nozzle station 5C is provided in nozzle feeder 5A in an attachable and detachable manner. Nozzle station 5C is disposed to be liftable and lowerable to exchange position 5D set in an upper rear portion of frame body 5B. Nozzle station 5C is one form of a mounting tool station that exchangeably holds multiple component mounting tools (suction nozzles 95). The quantity of suction nozzles 95 held by nozzle station 5C is set to be larger than the maximum number of suction nozzles 95 provided in nozzle tool 944. According to this, nozzle feeder 5A can collectively supply all suction nozzles 95 to be exchanged by nozzle tool 944 during changeover.

Nozzle station 5C includes a base plate and a cover plate (not shown). The base plate is formed in a rectangular shape in a plan view, and includes multiple housing holes capable of respectively housing suction nozzles 95. The cover plate slides and moves above the base plate and moves between an open position and a restriction position. The cover plate enables suction nozzle 95 to be housed in and removed from the base plate when located at the open position, and restricts suction nozzle 95 from being housed in and removed from the base plate when located at the restriction position.

As shown in FIG. 4, lifting and lowering drive section 5M and restriction drive section 5N are provided in front of nozzle station 5C. Lifting and lowering drive section 5M drives nozzle station 5C to be lifted and lowered between an exchange position on an upper side and a standby position on a lower side via a transmission mechanism (details not shown). By standing by at the standby position, nozzle station 5C is prevented from interfering with suction nozzle 95 that performs the mounting work. After the mounting work is ended, nozzle station 5C is lifted to the exchange position, and a state in which suction nozzle 95 can be exchanged is reached. Restriction drive section 5N drives the sliding movement of the cover plate via a transmission mechanism (details not shown). An electric power source, for example, an electromagnetic solenoid can be used as lifting and lowering drive section 5M and restriction drive section 5N.

Nozzle feeder control section 5E is disposed at a front lower portion of frame body 5B. Nozzle feeder control section 5E is communicably connected to the control device of component mounter 9 via the connector. The control device acquires individual identification information and various unique information of nozzle feeder 5A via communication with nozzle feeder control section 5E. In addition, nozzle feeder control section 5E may store individual identification information and various unique information of nozzle station 5C and suction nozzle 95 held in nozzle feeder 5A. In this case, the control device may simultaneously acquire these pieces of information via the communication with nozzle feeder control section 5E. Meanwhile, nozzle feeder control section 5E controls lifting and lowering drive section 5M and restriction drive section 5N according to a command from the control device, and monitors a state of lock mechanism 5K. The protrusion, upper positioning pin 5G, the lower positioning pin, the connector, and lock mechanism 5K have the same configuration and function as the corresponding portions of tape feeder 3A. Accordingly, the description of these portions will be omitted.

### 5. Configuration of Feeder Storage System 1 of Embodiment

### 5.1 Overall Configuration

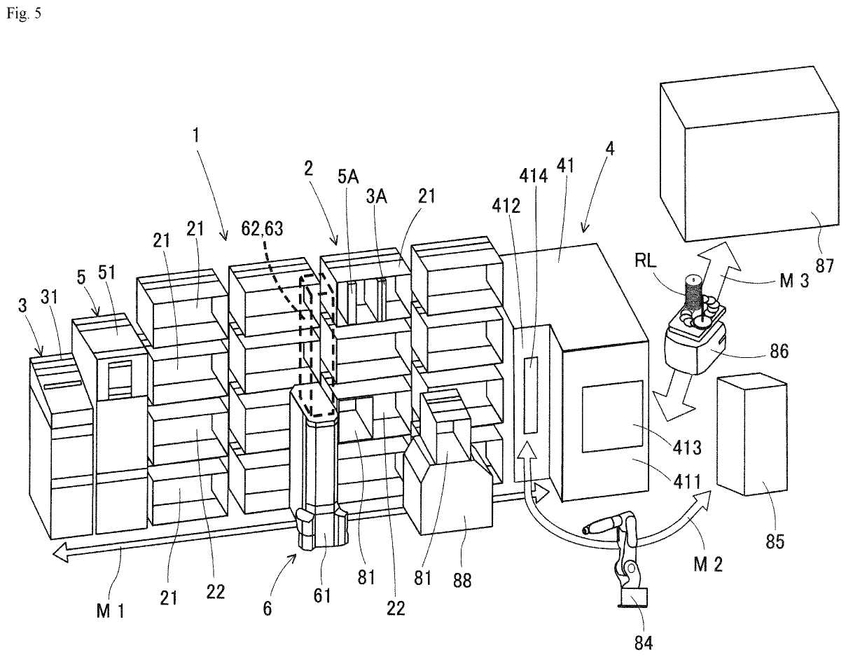

Next, a configuration of feeder storage system 1 of the embodiment will be described with reference to FIGS. 5 to 10. Feeder storage system 1 not only simply stores tape feeder 3A and nozzle feeder 5A, but also automates or saves labor in maintenance and setup of tape feeder 3A and nozzle feeder 5A, conveyance in the system, and conveyance with an outside of the system. Feeder storage system 1 includes storage 2, feeder maintenance device 3, reel attachment/detachment device 4, nozzle operation device 5, conveyance device 6, and control device 7 (refer to FIG. 11).

In the example of the overall configuration shown in FIG. 5, feeder maintenance device 3, nozzle operation device 5, storage 2, and reel attachment/detachment device 4 are arranged in order from a left side. An arrangement order of these devices and the like is not limited. In the present embodiment, these devices and the like are arranged such that their front surfaces are aligned in a straight line, and adjacent devices are in contact with each other or small gaps are provided between the devices. Accordingly, movement efficiency and conveyance efficiency of conveyance device 6 are improved. The disclosure is not limited thereto, and the front surfaces of these devices and the like may be arranged along a curved surface. However, excessive gaps between the devices are not preferable because a moving distance of conveyance device 6 is increased and the conveyance efficiency is reduced.

### 5.2 Storage 2

Storage 2 stores multiple tape feeders 3A and nozzle feeders 5A. Storage 2 is configured such that plurality of storage sections (21, 22) are arranged in a vertical direction (vertical direction) and a left-right direction (horizontal direction). Each of the storage sections (21, 22) has a substantially horizontal rectangular parallelepiped shape having a width dimension larger than a depth dimension and a height dimension. A front surface of each of the storage sections (21, 22) is omitted, and a storage target can be taken in and out. In the example shown in FIG. 5, the storage sections (21, 22) are stacked in four stages in the up-down direction and arranged in four rows in the left-right direction, and a total of 16 storage sections are provided.

Each of the storage sections 21 in the first, third, and fourth stages from the bottom has multiple storage positions arranged in the width direction. Storage section 21 stores tape feeder 3A or nozzle feeder 5A at each of the multiple storage positions. That is, tape feeder 3A and nozzle feeder 5A have compatibility in terms of the storage position of storage section 21 in addition to compatibility in terms of the mounting position of pallet table 931. Storage section 21 has a width dimension substantially equal to that of pallet table 931 of component mounter 9, and has a storage capacity with which it is possible to store the same number of tape feeders 3A and nozzle feeders 5A as the maximum number of feeders that can be mounted on pallet table 931. Storage section 21 in the third row from the left in the fourth stage from the bottom illustrated in FIG. 5 stores two tape feeders 3A and one nozzle feeder 5A. A loading operation of accommodating tape feeder 3A or nozzle feeder 5A at the storage position of storage section 21 and an unloading operation of pulling out tape feeder 3A or nozzle feeder 5A in a reverse direction are mainly performed by conveyance device 6, but may be performed by a worker.

Storage section 21 includes a communication interface section (not illustrated) that is automatically fitted to connector 3J of tape feeder 3A and the connector of nozzle feeder 5A which are accommodated in the storage positions. The communication interface section is communicably connected to control device 7. Accordingly, feeder control section 3E of tape feeder 3A and nozzle feeder control section 5E of nozzle feeder 5A are communicably connected to control device 7. Control device 7 acquires the individual identification information and the various unique information of each of tape feeder 3A and nozzle feeder 5A by performing communication. Further, control device 7 may simultaneously acquire the individual identification information and the various unique information of each of reel RL attached to tape feeder 3A, and nozzle station 5C and suction nozzle 95 attached to nozzle feeder 5A. The acquisition of the information through control device 7 may be performed only when tape feeder 3A and nozzle feeder 5A are accommodated in the storage position and when they are pulled out, or may be performed periodically.

Each of storage sections 22 in the second stage from the bottom has two magazine storage positions arranged in the width direction therein. That is, storage section 22 has a storage capacity with which it is possible to store two feeder magazines 81. Storage section 22 in the third row from the left in the second stage from the bottom illustrated in FIG. 5 stores feeder magazine 81 at the magazine storage position on the left side. Disposing storage section 22 in the second stage from the bottom and a height position of storage section 22 are determined in accordance with a height of a loading platform of magazine conveyance vehicle 88 to be described later. Note that the quantity, disposition, storage capacity, and storage target of storage sections (21, 22) can be variously changed.

Feeder magazine 81 is used for the purpose of improving efficiency of conveyance work between storage 2 and component mounter 9. Feeder magazine 81 is formed in a box shape in which at least one of a front surface and a rear surface is omitted. Feeder magazine 81 has multiple accommodation positions arranged in the width direction therein, in other words, has an accommodation capacity with which it is possible to accommodate multiple tape feeders 3A. Feeder magazine 81 may accommodate multiple tape feeders 3A, or may accommodate multiple combinations of tape feeder 3A and nozzle feeder 5A. An operation of accommodating tape feeder 3A or nozzle feeder 5A in feeder magazine 81 stored in storage section 22 and an operation of taking out tape feeder 3A or nozzle feeder 5A in a reverse direction are mainly performed by conveyance device 6, but may be performed by the worker.

Feeder magazine 81 is formed in a substantially half size of the width dimension of pallet table 931 of component supply device 93 in the X-axis direction. Therefore, by using two feeder magazines 81, total changeover can be performed on all tape feeders 3A and nozzle feeders 5A mounted on pallet table 931. Feeder magazine 81 may be formed in a full size substantially equal to the width dimension of pallet table 931, which enables the total changeover by one use. In this aspect, storage section 22 has one magazine storage position for storing feeder magazine 81 of the full size.

### 5.3 Feeder Maintenance Device 3

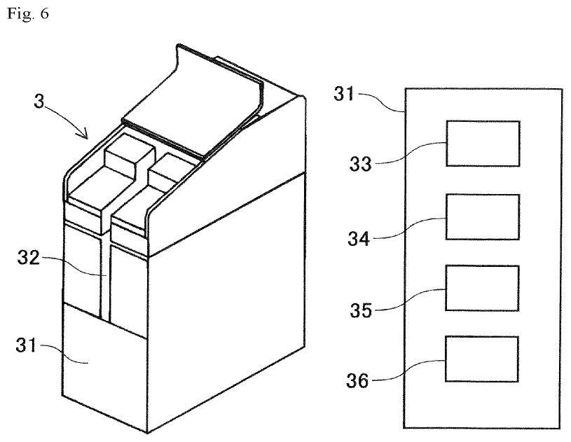

Feeder maintenance device 3 performs maintenance on tape feeder 3A, to which reel RL is not attached, as a target. As shown in FIG. 6, feeder maintenance device 3 is configured by providing cleaning unit 33, adjustment unit 34, inspection unit 35, control unit 36, and the like inside housing 31. Housing 31 has a vertically long box shape, and feeder insertion opening 32 is provided substantially at a center of a front surface thereof. An operation of inserting tape feeder 3A into housing 31 through feeder insertion opening 32 and an operation of taking out tape feeder 3A in a reverse direction are mainly performed by conveyance device 6, but may be performed by the worker. Feeder maintenance device 3 may include multiple sets of feeder insertion opening 32, cleaning unit 33, adjustment unit 34, and inspection unit 35, and perform maintenance of multiple tape feeders 3A in parallel.

Cleaning unit 33 cleans tape feeding mechanism 3C of tape feeder 3A. Specifically, cleaning unit 33 blows air to a sprocket or the like of tape feeding mechanism 3C to blow off and remove foreign matter such as dust. A cleaning target includes, in addition to the sprocket, a transmission mechanism such as a gear, a tape detection section, and a roller that assists feeding of the carrier tape. Further, cleaning unit 33 may perform cleaning by blowing air to reel accommodation frame 3B1 and lock mechanism 3K. In addition, cleaning unit 33 removes old lubricant adhering to a meshing portion of the gear of the transmission mechanism by spraying a cleaning liquid thereto. A type, a supply amount, and a cleaning target location of the cleaning fluid (air, cleaning liquid) to be used in a cleaning process may be appropriately changed according to a difference in the type or structure of tape feeder 3A.

Adjustment unit 34 adjusts tape feeding mechanism 3C and the like of tape feeder 3A. Specifically, adjustment unit 34 performs adjustment for accurately pitch-feeding the carrier tape by rotating the sprocket of tape feeding mechanism 3C by a certain amount. Adjustment unit 34 measures, for example, an actual feed amount of the carrier tape when the sprocket is rotated by the certain amount with high accuracy, and corrects a command operation amount to the drive source as necessary. Further, adjustment unit 34 supplies lubricant to the meshing portion of the gear of the transmission mechanism and the like. A type, a supply amount, and a supply location of the lubricant to be used may be appropriately changed according to the difference in the type or structure of tape feeder 3A.

Inspection unit 35 performs various inspections on at least one of tape feeder 3A before the cleaning or the adjustment is performed and tape feeder 3A after the cleaning or the adjustment is performed as a target. In the present embodiment, inspection items of inspection unit 35 include operation accuracy of tape feeding mechanism 3C, a drive load, and detection sensitivity of the tape detection section. For example, inspection unit 35 operates tape feeding mechanism 3C to measure the actual feed amount of the carrier tape and torque required for the operation, and obtains the operation accuracy of tape feeding mechanism 3C and the drive load. Thus, inspection unit 35 can check whether a function of tape feeding mechanism 3C is deteriorated, a degree of the deterioration, a quality of lubricity, a degree of contamination, and the like. Inspection unit 35 measures the detection sensitivity by causing, for example, the tape detection section to detect an inspection subject. Accordingly, inspection unit 35 can check, for example, whether dirt adheres to the tape detection section.

Inspection unit 35 records the inspection date and time, a quality determination result of each inspection item, and the basis of the determination, for example, a measurement value, for each individual identification information of tape feeder 3A which is an inspection target. In addition, inspection unit 35 may determine whether maintenance is necessary in a first inspection for tape feeder 3A before the cleaning or the adjustment is performed as a target. In this aspect, inspection unit 35 performs re-inspection by appropriately resetting the inspection items in tape feeder 3A in which maintenance is determined to be necessary in the first inspection and the cleaning or the adjustment is performed, and performs final quality determination.

Control unit 36 is a controller including CPU, various memories, a control circuit, and the like. Control unit 36 is communicably connected to feeder control section 3E via connector 3J of inserted tape feeder 3A. Control unit 36 acquires the individual identification information and the various unique information of tape feeder 3A via the communication with feeder control section 3E. Control unit 36 is communicably connected to control device 7, and is configured to share various information. Control unit 36 controls a cleaning operation of cleaning unit 33, an adjustment operation of adjustment unit 34, and an inspection operation of inspection unit 35 based on a command from control device 7.

### 5.4 Reel Attachment/Detachment Device 4

Reel attachment/detachment device 4 attaches and detaches reel RL to and from tape feeder 3A. As shown in FIG. 5, reel attachment/detachment device 4 has box-shaped housing 41 larger than feeder maintenance device 3 and nozzle operation device 5. Right front surface 411 on a front side of housing 41 protrudes forward with respect to left front surface 412. Reel attachment/detachment device 4 is disposed such that left front surface 412 of housing 41 is aligned with a front surface of storage 2 in a straight line. Reel loading opening 413 is provided on right front surface 411 of housing 41, and feeder insertion opening 414 is provided on left front surface 412.

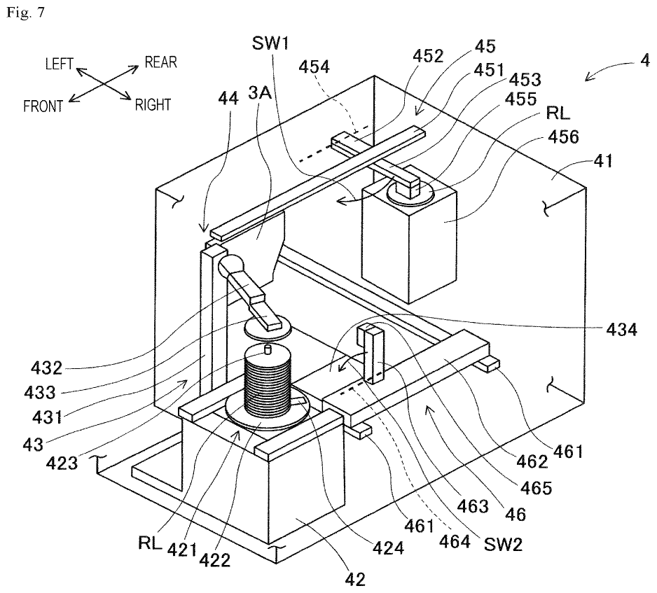

As shown in FIG. 7, reel attachment/detachment device 4 is configured by assembling various constituent members inside housing 41. Specifically, reel attachment/detachment device 4 includes reel loading table 42, reel transfer mechanism 43, feeder holding section 44, reel detachment mechanism 45, reel attachment mechanism 46, and a control unit (not shown). Reel loading table 42 is disposed on a rear side of reel loading opening 413. Reel loading table 42 has a pedestal shape, and reel holding body 421 is placed thereon.

Reel holding body 421 includes disk-shaped holding plate 422 that is horizontally disposed and round bar-shaped holding shaft 423 that stands upright from the center of holding plate 422. According to this, reel holding body 421 can place multiple (for example, 20) reels RL in a lying posture on holding plate 422 and hold reels RL by inserting holding shaft 423 into a center hole of each reel RL. Identification code 424 for identifying individual reel holding body 421 is attached near an outer periphery of holding plate 422. Identification code 424 is associated with the individual identification information of placed reel RL. Identification code 424 is identified by a code reader (not shown) provided in housing 41. An operation of loading reel holding body 421 through reel loading opening 413 and placing reel holding body 421 on reel loading table 42 and an operation of taking out reel holding body 421 in a reverse direction are mainly performed by reel conveyance vehicle 86 to be described later, but may be performed by the worker.

Reel transfer mechanism 43 includes support column 431, arm 432, collection section 433, placement area 434, and the like. Support column 431 is provided upright in vicinity of reel loading table 42. Arm 432 is provided to be liftable and lowerable, and rotatable with respect to support column 431. Collection section 433 is provided at a distal end of arm 432, and detachably collects reel RL on a lower side thereof. As a collection method of collection section 433, a gripping method of gripping a claw portion formed on reel RL or a peripheral edge of reel RL, a pickup method of picking up reel RL using a negative pressure, or the like can be adopted. Placement area 434 is disposed on a rear side of reel loading table 42. Reel transfer mechanism 43 takes out reel RL from reel holding body 421 by operations of arm 432 and collection section 433, and places reel RL on placement area 434 while maintaining the lying posture.

Feeder holding section 44 is disposed on a rear side of feeder insertion opening 414. Feeder holding section 44 holds tape feeder 3A inserted through feeder insertion opening 414 in a standing posture. Feeder holding section 44 opens accommodation plate 3B2 and accommodation plate 3B3 of tape feeder 3A to hold the feeder in a state in which reel RL is exchangeable. An operation of inserting tape feeder 3A into feeder holding section 44 through feeder insertion opening 414 and an operation of taking out tape feeder 3A in a reverse direction are mainly performed by conveyance device 6 or feeder conveyance robot 84 to be described later, but may be performed by the worker.

Reel detachment mechanism 45 includes guide rail 451, moving table 452, detachment body 453, and retrieval box 456. Guide rail 451 is provided in vicinity of a ceiling of housing 41 and extends in a front-rear direction. Moving table 452 is mounted below guide rail 451 and moves in the front-rear direction. Detachment body 453 swings about swing shaft 454 provided on moving table 452 between a horizontal posture shown in FIG. 7 and a vertical posture in which detachment body 453 hangs downward (refer to arrow SW1 in FIG. 7). Detachment body 453 includes collection section 455 at an end portion on a side away from swing shaft 454. Collection section 455 collects reel RL from tape feeder 3A. A collection method of collection section 455 may be the same as or different from that of collection section 433. Retrieval box 456 has a box shape that opens upward, and is disposed below a rear portion of guide rail 451.

Reel detachment mechanism 45 moves moving table 452 to the front side and swings detachment body 453 from the horizontal posture to the vertical posture, thereby collecting reel RL from tape feeder 3A with collection section 455. Next, reel detachment mechanism 45 returns detachment body 453 holding reel RL from the vertical posture to the horizontal posture, and moves moving table 452 rearward. Next, in reel detachment mechanism 45, collection section 455 releases reel RL and drops reel RL toward retrieval box 456. Accordingly, reel detachment mechanism 45 can detach reel RL from tape feeder 3A. The reel detachment mechanism 45 may drop used reel RL in which the carrier tape is used up into retrieval box 456 and drop reel RL in which the carrier tape is partially used into a reuse box (not shown).

Reel attachment mechanism 46 includes pair of guide rails 461, moving table 462, and attachment body 463. Pair of guide rails 461 extends in the left-right direction at a position near a front portion of housing 41 and at a substantially central position in the front-rear direction, and guide rails 461 are disposed in parallel to be separated from each other. Moving table 462 is formed of a member elongated in the front-rear direction, and is mounted over upper sides of pair of guide rails 461. Moving table 462 reciprocates along guide rails 461 between the standby position on the right portion shown in FIG. 7 and a work position close to feeder holding section 44.

Attachment body 463 is formed of a member having a substantially square bar shape, and is provided to extend upward from a right side surface of moving table 462. Attachment body 463 faces a side surface of tape feeder 3A held by feeder holding section 44. Attachment body 463 swings about swing shaft 464 provided at a location close to moving table 462 between a vertical posture illustrated in FIG. 7 and a horizontal posture in which attachment body 463 lies down to the left side (refer to arrow SW2 in FIG. 7). Collection section 465 is provided at an end portion on a side of attachment body 463 away from swing shaft 464. Collection section 465 detachably collects reel RL. A collection method of collection section 465 may be the same as or different from that of collection section 433 or collection section 455.

Reel attachment mechanism 46 operates after feeder holding section 44 holds tape feeder 3A and reel transfer mechanism 43 places reel RL on placement area 434. Specifically, reel attachment mechanism 46 slightly moves moving table 462 from the standby position in a direction toward feeder holding section 44, and causes attachment body 463 to swing from the vertical posture to the horizontal posture, thereby collecting reel RL with collection section 465. Next, reel attachment mechanism 46 returns attachment body 463 from the horizontal posture to the vertical posture, and stands held reel RL vertically. Next, reel attachment mechanism 46 attaches reel RL held by collection section 465 to tape feeder 3A by advancing moving table 462 to the work position. Reel attachment mechanism 46 may include a tape loading mechanism that pulls out the carrier tape from attached reel RL and advances the carrier tape to supply position 3D.

The control unit (not shown) is a controller including CPU, various memories, a control circuit, and the like. The control unit controls reel transfer mechanism 43, feeder holding section 44, reel detachment mechanism 45, and reel attachment mechanism 46. Based on a command from control device 7, the control unit controls execution of any one of only attachment work of reel RL, only detachment work of reel RL, and the detachment work of reel RL and attachment work of another reel RL with respect to held tape feeder 3A as a target. Further, the control unit reports association between tape feeder 3A and reel RL (association of individual identification information) or release of the association to management device 70 to be described later in accordance with the executed work.

### 5.5 Nozzle Operation Device 5

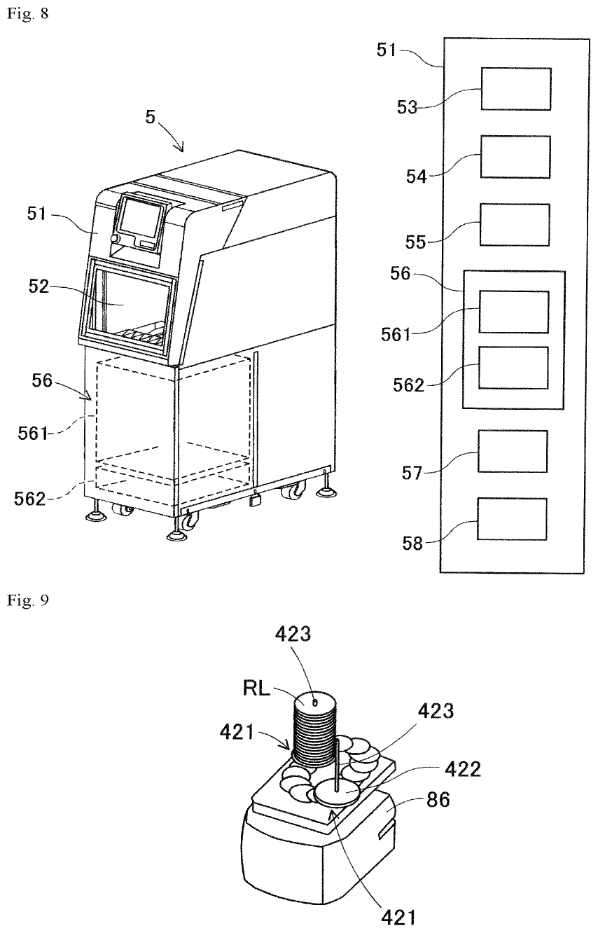

Nozzle operation device 5 performs storage, maintenance, and an attachment/detachment operation to and from nozzle feeder 5A, for suction nozzle 95. Nozzle operation device 5 is one form of a mounting tool operation device that performs at least one of storage, maintenance, and an attachment/detachment operation to and from the mounting tool feeder, for the component mounting tool. As shown in FIG. 8, nozzle operation device 5 is configured such that nozzle moving device 53, cleaning unit 54, inspection unit 55, storage unit 56, control unit 57, discharge box 58, and the like are provided inside housing 51.

Housing 51 has a vertically long box shape, and feeder holding section 52 is provided substantially at the center thereof. Feeder holding section 52 can respectively hold nozzle feeders 5A at multiple holding positions arranged in the width direction. Feeder holding section 52 holds nozzle feeders 5A as targets of maintenance at least at some of the multiple holding positions. In addition, feeder holding section 52 can store nozzle feeders 5A while maintaining current states of nozzle feeders 5A by using the rest of the multiple holding positions as the storage positions. An operation of inserting nozzle feeder 5A into feeder holding section 52 and an operation of taking out nozzle feeder 5A in a reverse direction are mainly performed by conveyance device 6, but may be performed by the worker.

Nozzle moving device 53 can detach nozzle station 5C from nozzle feeder 5A held by feeder holding section 52 and move nozzle station 5C to each part in the device. In addition, nozzle moving device 53 can detach suction nozzles 95 one by one from nozzle station 5C attached to nozzle feeder 5A and move suction nozzle 95 to each part in the device. Nozzle moving device 53 may use a movement pallet for placing and moving multiple detached suction nozzles 95. A shape of the movement pallet may be the same as or different from that of nozzle station 5C. Meanwhile, nozzle moving device 53 can perform setup work of attaching nozzle station 5C temporarily stored or nozzle station 5C set up by being caused to hold suction nozzle 95 in the device to nozzle feeder 5A. In addition, nozzle moving device 53 can also perform setup work of causing nozzle station 5C attached to nozzle feeder 5A to hold suction nozzles 95 one by one.

Cleaning unit 54 cleans and dries the air flow path and the expansion and contraction portion of suction nozzle 95 in a cleaning chamber (not shown). Cleaning unit 54 performs cleaning by, for example, circulating a high-pressure cleaning fluid (air, cleaning liquid) inside suction nozzle 95. Cleaning unit 54 cleans an outer surface of suction nozzle 95 by spraying a high-pressure cleaning liquid, for example, cleaning water thereto. Further, cleaning unit 54 blows warm air or cool air to cleaned suction nozzle 95 with, for example, a blowing device (not shown) to blow off the cleaning water and dry it.

Inspection unit 55 performs various inspections on at least one of suction nozzle 95 before the cleaning is performed and suction nozzle 95 after the cleaning is performed as a target. In the present embodiment, inspection items of inspection unit 55 include an outer shape of suction nozzle 95, a flow rate of a negative-pressure flow path, and sliding resistance of the expansion and contraction portion. Inspection unit 55 images, for example, suction nozzle 95 held by nozzle moving device 53 with an optical camera (not shown), and inspects the outer shape of suction nozzle 95 based on image data acquired by the imaging. As a result, inspection unit 55 can check whether there is a strain, a defect, adhering matter, or the like in suction nozzle 95.

Inspection unit 55 measures a load when nozzle shaft 954 of suction nozzle 95 slides toward the inside of body shaft 951 by using a load sensor (not shown) such as a load cell. By comparing a measured value of the load with a predetermined specified value, inspection unit 55 can check whether the sliding resistance is increased because of a factor such as contamination of a sliding portion of suction nozzle 95. Inspection unit 55 records the inspection date and time, a quality determination result of each inspection item, and the basis of the determination, for example, a measurement value, for each individual identification information of suction nozzle 95 which is an inspection target. In addition, inspection unit 55 may determine whether maintenance is necessary in a first inspection for suction nozzle 95 before the cleaning is performed as a target. In this aspect, inspection unit 55 performs re-inspection by appropriately resetting the inspection items in suction nozzle 95 in which maintenance is determined to be necessary in the first inspection and the cleaning is performed, and performs final quality determination.

Storage unit 56 is disposed in a lower portion of housing 51 and stores multiple suction nozzles 95. Storage unit 56 is capable of either storing suction nozzles 95 one by one or storing nozzle station 5C as a unit. Storage unit 56 may store a storage pallet on which multiple suction nozzles 95 are placed. A shape of the storage pallet may be the same as or different from that of nozzle station 5C or the movement pallet. For example, the storage pallet is formed to be larger than nozzle station 5C, and a large number of suction nozzles 95 are placed and stored. In the present embodiment, storage unit 56 is divided into general area 561 in which the worker can take in and out suction nozzle 95 and management area 562 in which only an administrator having a predetermined authority can take in and out suction nozzle 95. Nozzle moving device 53 can take suction nozzle 95, nozzle station 5C, and the storage pallet into and out of both general area 561 and management area 562.

Control unit 57 is a controller including CPU, various memories, and a control circuit. Control unit 57 is communicably connected to nozzle feeder control section 5E via the connector of inserted nozzle feeder 5A. Control unit 57 acquires the individual identification information and the various unique information of nozzle feeder 5A via the communication with nozzle feeder control section 5E. Further, control unit 57 may simultaneously acquire the individual identification information and the various unique information of nozzle station 5C and suction nozzle 95 held in nozzle feeder 5A. Control unit 57 is communicably connected to control device 7 and is configured to share various information. Control unit 57 controls the movement operation of nozzle moving device 53, the cleaning operation of cleaning unit 54, and the inspection operation of inspection unit 55 based on a command from control device 7. Control unit 57 reports association between nozzle feeder 5A and nozzle station 5C and suction nozzle 95 or release of the association to management device 70 to be described later in accordance with the work executed by nozzle moving device 53. Discharge box 58 accumulates suction nozzles 95 determined to be defective based on an inspection result of inspection unit 55, for example. Discharge box 58 is partitioned into multiple spaces, and can be used for sorting for each defect factor, for example.

### 5.6 Conveyance Device 6

As indicated by arrow M1 in FIG. 5, conveyance device 6 moves along an arrangement direction of feeder maintenance device 3, nozzle operation device 5, storage 2, and reel attachment/detachment device 4. Conveyance device 6 conveys tape feeders 3A between storage 2, feeder maintenance device 3, and reel attachment/detachment device 4. Conveyance device 6 conveys nozzle feeder 5A between storage 2 and nozzle operation device 5. Conveyance device 6 includes device main body 61, lifting and lowering section 62, and feeder operation section 63.

Device main body 61 includes a moving mechanism that moves along the arrangement direction. The moving mechanism includes, for example, traveling wheels and a drive source. The traveling wheels travel along traveling rails (not shown) provided on the front surfaces of feeder maintenance device 3, nozzle operation device 5, storage 2, and reel attachment/detachment device 4. Alternatively, the traveling wheels move while traveling on a floor surface such that separation distances are constant between device main body 61, feeder maintenance device 3, nozzle operation device 5, storage 2, and reel attachment/detachment device 4. The drive source rotationally drives the traveling wheels. As the drive source, for example, a servo motor or a pulse motor having good controllability can be used. Further, as a power source of the drive source, for example, a battery or a non-contact power supply device can be used. As the moving mechanism, another type of mechanism such as a linear motor mechanism may be adopted.

Lifting and lowering section 62 is provided to be liftable and lowerable with respect to device main body 61. In other words, lifting and lowering section 62 expands and contracts with reference to device main body 61 between a lower limit position where lifting and lowering section 62 is accommodated in device main body 61 and an upper limit position indicated by a broken line in FIG. 5. A ball screw feed mechanism or a linear motor mechanism can be used as a lifting and lowering drive mechanism that drives lifting and lowering section 62. Feeder operation section 63 is provided in lifting and lowering section 62. By a lifting and lowering operation of lifting and lowering section 62, feeder operation section 63 can face any storage section (21, 22) from the lowest first stage to the highest fourth stage. In addition, conveyance device 6 may be configured such that device main body 61 is enlarged to reach storage section 21 in the fourth stage, lifting and lowering section 62 is omitted, and the lifting and lowering drive mechanism lifts and lowers feeder operation section 63 along device main body 61.

Feeder operation section 63 can hold at least one of tape feeder 3A and nozzle feeder 5A inside. Further, it is preferable that feeder operation section 63 can hold multiple combinations of tape feeder 3A and nozzle feeder 5A. According to this aspect, conveyance device 6 can perform conveyance work in which device main body 61 moves in a state in which feeder operation section 63 holds multiple tape feeders 3A and nozzle feeders 5A, and the conveyance efficiency is improved. Feeder operation section 63 performs a loading operation of accommodating held tape feeder 3A or held nozzle feeder 5A in storage section 21, and an unloading operation of extracting tape feeder 3A or nozzle feeder 5A stored in storage section 21 and holding tape feeder 3A or nozzle feeder 5A therein.

Feeder operation section 63 performs insertion and removal operation of tape feeder 3A and nozzle feeder 5A into and from feeder magazine 81 stored in storage section 22. Further, feeder operation section 63 performs an insertion operation of inserting held tape feeder 3A into feeder maintenance device 3 or reel attachment/detachment device 4, and removal operation in a reverse direction. Feeder operation section 63 performs an insertion operation of inserting held nozzle feeder 5A into nozzle operation device 5 and removal operation in a reverse direction. The present disclosure is not limited to the above, and the insertion operation and the take-out operation of tape feeder 3A may be performed on a side of feeder maintenance device 3 or reel attachment/detachment device 4, and the insertion operation and the take-out operation of nozzle feeder 5A may be performed on a side of nozzle operation device 5.

### 5.7 Second and Third Conveyance Devices

In the present embodiment, feeder storage system 1 uses feeder conveyance robot 84, reel conveyance vehicle 86, and magazine conveyance vehicle 88 in combination. Feeder conveyance robot 84 conveys tape feeder 3A between reel attachment/detachment device 4 and equipment warehouse 85 (member warehouse) as indicated by arrow M2 in FIG. 5. Reel attachment/detachment device 4 and equipment warehouse 85 are close to each other, and feeder conveyance robot 84 has a movable section such as an arm for conveyance and does not need to travel. Feeder conveyance robot 84 performs an operation of inserting tape feeder 3A into feeder holding section 44 through feeder insertion opening 414 of reel attachment/detachment device 4, and removal operation in a reverse direction. Further, feeder conveyance robot 84 may have a function of conveying nozzle feeder 5A between storage 2 and equipment warehouse 85. As feeder conveyance robot 84, for example, an articulated arm type robot can be used. Feeder conveyance robot 84 is one form of a second conveyance device that conveys tape feeder 3A between reel attachment/detachment device 4 and the member warehouse.

Reel conveyance vehicle 86 conveys reel RL between reel attachment/detachment device 4 and component warehouse 87 (member warehouse) as indicated by arrow M3 in FIG. 5. Reel attachment/detachment device 4 and component warehouse 87 are separated from each other, and reel conveyance vehicle 86 travels with reel RL loaded thereon. As shown in FIG. 9, reel conveyance vehicle 86 may convey reel holding body 421 holding multiple reels RL and convey empty reel holding body 421 not holding reel RL. Reel conveyance vehicle 86 can also convey single reel RL. Component warehouse 87 has a function of placing stored reel RL on reel holding body 421, a function of detaching reel RL from reel holding body 421 and storing reel RL, and a function of storing reel holding body 421 holding multiple reels RL as it is. Reel conveyance vehicle 86 performs an operation of loading reel holding body 421 or single reel RL through reel loading opening 413 of reel attachment/detachment device 4 and placing the reel on reel loading table 42, and an operation of taking out and loading the reel in a reverse direction. As reel conveyance vehicle 86, for example, an automated guided vehicle that automatically travels according to a wireless command can be used. Reel conveyance vehicle 86 is one form of the second conveyance device that conveys reel RL between reel attachment/detachment device 4 and the member warehouse.

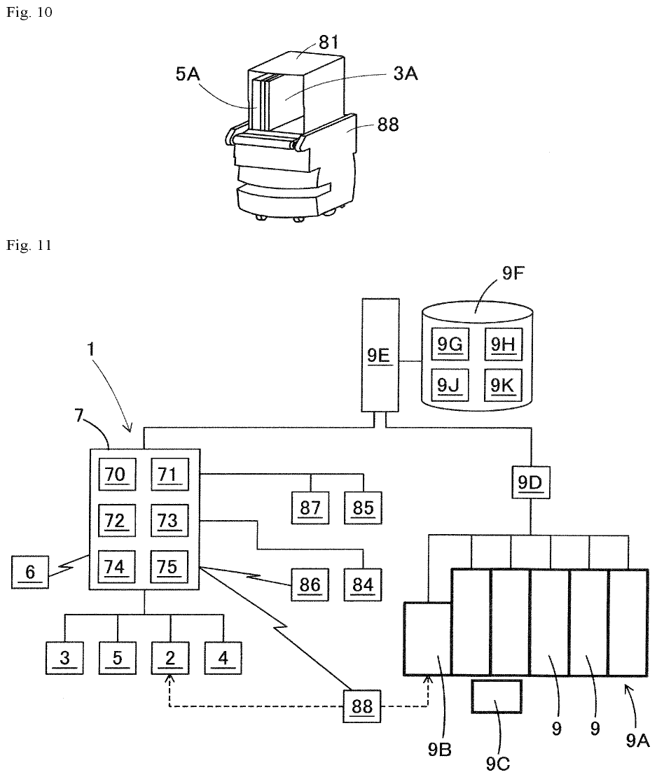

Magazine conveyance vehicle 88 conveys feeder magazine 81 between board work line 9A including component mounter 9 (specifically, buffer station 9B shown in FIG. 11) and storage 2. Board work line 9A and storage 2 are separated from each other, and magazine conveyance vehicle 88 travels with feeder magazine 81 loaded thereon. As shown in FIG. 10, magazine conveyance vehicle 88 may convey feeder magazine 81 accommodating tape feeder 3A and nozzle feeder 5A, and convey empty feeder magazine 81. Magazine conveyance vehicle 88 can also convey single tape feeder 3A and single nozzle feeder 5A. Magazine conveyance vehicle 88 performs an operation of storing feeder magazine 81 in storage section 22 and an operation of taking out and loading feeder magazine 81 in a reverse direction. As magazine conveyance vehicle 88, for example, an automated guided vehicle that automatically travels according to a wireless command can be used. Magazine conveyance vehicle 88 is one form of a third conveyance device that conveys tape feeder 3A and the mounting tool feeder (nozzle feeder 5A) between component mounter 9 or board work line 9A and storage 2.

### 6. Overall Configuration Regarding Control of Feeder Storage System 1

Next, an overall configuration related to control of feeder storage system 1 will be described with reference to FIG. 11. Control device 7 is configured using a computer device including CPU, various memories, a control circuit, a communication circuit, and the like. Control device 7 acquires the individual identification information and the various unique information from feeder control section 3E of tape feeder 3A and nozzle feeder control section 5E of nozzle feeder 5A stored in storage 2 via communication through a communication interface section of storage section 21. Further, control device 7 issues a command to each of control unit 36 of feeder maintenance device 3, the control unit of reel attachment/detachment device 4, and control unit 57 of nozzle operation device 5, which are communicably connected, to control them. Further, control device 7 issues a command to conveyance device 6 via wireless communication to perform control.

Control device 7 is communicably connected to a warehouse control section (not shown) of equipment warehouse 85, and can recognize an inventory situation of tape feeder 3A and nozzle feeder 5A stored in equipment warehouse 85. Further, control device 7 issues a command to feeder conveyance robot 84 via wired communication to control feeder conveyance robot 84. Further, control device 7 is communicably connected to a warehouse control section (not shown) of component warehouse 87, and can recognize an inventory situation of reel RL stored in component warehouse 87. Further, control device 7 issues a command to reel conveyance vehicle 86 via wireless communication to control reel conveyance vehicle 86. Further, control device 7 issues a command to magazine conveyance vehicle 88 via wireless communication to control magazine conveyance vehicle 88.

Control device 7 is communicably connected to production management device 9E. Further, production management device 9E is communicably connected to line management device 9D. Line management device 9D is communicably connected to multiple board work machines including component mounter 9, and manages board work line 9A in which the multiple board work machines are arranged. In FIG. 11, board work line 9A includes two component mounters 9 as targets to which tape feeder 3A and nozzle feeder 5A are supplied, but may include one or three or more component mounters 9. Further, feeder storage system 1 and production management device 9E may be commonly provided for multiple sets of board work line 9A and line management device 9D.

In the present embodiment, board work line 9A includes buffer station 9B and line conveyance device 9C. Buffer station 9B is a place where magazine conveyance vehicle 88 arrives and loads and unloads feeder magazine 81, and temporarily stores feeder magazine 81. Buffer station 9B can be configured to have the same structure as storage section 22 of storage 2, and may have a structure different from storage section 22.

Line conveyance device 9C performs a conveyance operation according to a command from line management device 9D, for example, a wireless command. Line conveyance device 9C conveys and exchanges tape feeder 3A and nozzle feeder 5A between feeder magazine 81 temporarily stored in buffer station 9B and pallet table 931 of component mounter 9. Specifically, when tape feeder 3A on pallet table 931 runs out of components during an operation of component mounter 9, line conveyance device 9C detaches tape feeder 3A and accommodates tape feeder 3A in feeder magazine 81 of buffer station 9B. Next, line conveyance device 9C replenishes components by conveying another tape feeder 3A from feeder magazine 81 to pallet table 931 and mounting tape feeder 3A on pallet table 931.

In addition, in a case of changeover in which board K produced by component mounter 9 is switched from a current board type to a next board type, line conveyance device 9C detaches tape feeder 3A which is not used for the production of the next board type among multiple tape feeders 3A on pallet table 931 and accommodates tape feeder 3A in feeder magazine 81. Next, line conveyance device 9C conveys tape feeder 3A to be used for the production of the next board type from feeder magazine 81 to pallet table 931 and mounts tape feeder 3A on pallet table 931.

Further, in a case of the changeover, line conveyance device 9C detaches nozzle feeder 5A, which has retrieved suction nozzle 95 not used for the production of the next board type, from pallet table 931 and accommodates nozzle feeder 5A in feeder magazine 81. Next, line conveyance device 9C conveys another nozzle feeder 5A holding suction nozzle 95 to be used for the production of the next board type from feeder magazine 81 to pallet table 931 and mounts nozzle feeder 5A on pallet table 931. Alternatively, line conveyance device 9C may first mount nozzle feeder 5A holding suction nozzle 95 to be used for the production of the next board type on pallet table 931. In this aspect, component transfer device 94 performs a retrieval operation of detaching suction nozzle 95 not used for the production of the next board type from nozzle tool 944 and retrieving suction nozzle 95 to nozzle feeder 5A. Next, component transfer device 94 performs an attachment operation of attaching suction nozzle 95 to be used for the production of the next board type from nozzle feeder 5A to nozzle tool 944. Then, component transfer device 94 repeats the retrieval operation and the attachment operation.

Pallet table 931 of component mounter 9 may be equipped with feeder magazine 81, and tape feeder 3A and nozzle feeder 5A accommodated in feeder magazine 81 may be in an operating state. In this aspect, line conveyance device 9C conveys feeder magazine 81 between buffer station 9B and pallet table 931. Buffer station 9B and line conveyance device 9C may be omitted, and magazine conveyance vehicle 88 may directly convey at least one of feeder magazine 81, tape feeder 3A, and nozzle feeder 5A to component mounter 9.

Production management device 9E stores and manages production plan 9G, equipment history data 9J, and component history data 9K of multiple types of boards K in attached memory 9F. Production plan 9G includes at least a production order and a production quantity of multiple types of boards K. Production plan 9G is associated with mounting work data 9H created for each type of board K. Therefore, mounting work data 9H can be rephrased as a detailed part of production plan 9G.

Mounting work data 9H includes information on the type and shape of board K, and information on the type, quantity, and mounting coordinates of the components to be mounted on board K. Further, mounting work data 9H includes combination information defining a combination of tape feeder 3A and reel RL to be used. This combination information is information that defines a combination of the type of tape feeder 3A and the type of component supplied by reel RL, and is not information that specifies a combination of individual tape feeder 3A and individual reel RL.

Equipment history data 9J is data in which various histories such as an operation history and a maintenance history of equipment such as tape feeder 3A or suction nozzle 95 are stored. The operation history includes, for example, information such as the number of operations of the equipment, the type of board K or the component as an operation target, a quality of each operation, and an error rate indicating an occurrence rate of operation failure. The maintenance history includes, for example, information such as an execution time of maintenance, an execution content, a result of a performance check test after execution of maintenance, and a recommended time of next maintenance.

Component history data 9K is data in which various histories such as a procurement history and a use history of reel RL and the carrier tape are stored. The procurement history includes information on a production time (such as a manufacturing year and month) and a procurement time of the component. The use history includes information on the use time and the use quantity of the components, and information on the used equipment and the board K on which mounting is performed. The use history further includes information on the remaining number of components.

Production management device 9E estimates a time when tape feeder 3A of component mounter 9 runs out of components based on the information on a progress situation of the mounting work received from line management device 9D. Then, production management device 9E transmits a tape setup command for setting up tape feeder 3A to be used next and a conveyance command for conveying setup tape feeder 3A to component mounter 9 to control device 7 in a timely manner to shorten a production interruption time due to component shortage.

Production management device 9E estimates a time of changeover for switching board K to be produced from the current board type to the next board type based on the information on the progress situation of the mounting work and production plan 9G. Then, production management device 9E transmits a changeover command to control device 7 in a timely manner to shorten the production interruption time due to the changeover. The changeover command includes a tape setup command, a nozzle setup command, and a conveyance command. The tape setup command is a command for setting up multiple tape feeders 3A to be used in the changeover. The nozzle setup command is a command for setting up nozzle feeder 5A to be used in the changeover. The conveyance command is a command for conveying tape feeder 3A and nozzle feeder 5A that have been set up to buffer station 9B. When nozzle feeder 5A is not used in the changeover, production management device 9E omits the nozzle setup command from the changeover command.

Production management device 9E transmits a retrieval command to control device 7 in a timely manner for tape feeder 3A and nozzle feeder 5A detached from component mounter 9 as targets. The retrieval command includes a conveyance command, a maintenance command, and a storage command. The conveyance command is a command for conveying feeder magazine 81 accommodating detached tape feeder 3A and detached nozzle feeder 5A from buffer station 9B to storage 2. Production management device 9E sets the recommended time of maintenance based on the operation history of each of tape feeder 3A and suction nozzle 95 indicated in equipment history data 9J. Production management device 9E transmits the maintenance command for performing maintenance of tape feeder 3A and suction nozzle 95 based on the recommended time. Production management device 9E transmits the storage command for designating a storage place of tape feeder 3A and suction nozzle 95 and storing tape feeder 3A and suction nozzle 95 based on a future use schedule indicated by mounting work data 9H in production plan 9G. When there is no maintenance execution target, production management device 9E omits the maintenance command from the retrieval command.

Meanwhile, control device 7 can share or recognize production plan 9G, equipment history data 9J, and component history data 9K. In addition, control device 7 receives the tape setup command, the nozzle setup command, the conveyance command, the maintenance command, and the storage command from production management device 9E, and performs control according to the commands. Further, control device 7 receives the changeover command and the retrieval command from production management device 9E and performs control according to various commands included therein. Hardware configurations of production management device 9E, line management device 9D, and control device 7, distribution of functions achieved by software, and a storage area of various information can be modified in addition to those described above.

### 7. Control Performed by Control Device 7

Next, control performed by control device 7 will be described. Control device 7 includes a function of management device 70 in charge of inventory control and the like of storage 2. Management device 70 manages the storage situation of tape feeder 3A and nozzle feeder 5A stored in storage 2 as information. The storage status information from tape feeder 3A includes the individual identification information of tape feeder 3A, the information on the storage position in storage 2, the information on whether reel RL is attached, the individual identification information of attached reel RL, and the information on the type of the component to be supplied. The storage status information from nozzle feeder 5A includes the individual identification information of nozzle feeder 5A, the information on the storage position, and the individual identification information of nozzle station 5C and suction nozzle 95. Further, the storage status information may include a period until the present during which tape feeder 3A and nozzle feeder 5A have been stored, information on whether maintenance has been performed during storage, and the like. Management device 70 may be separated from control device 7. In addition, a part of the storage status information may be stored in a memory of another device and may be accessed by management device 70.

Control device 7 determines the storage position of tape feeder 3A inside storage 2 based on the storage status information from management device 70. Specifically, control device 7 selects at least one storage mode among first to sixth storage modes to be described below, and determines the storage position of tape feeder 3A based on the storage mode.

First storage mode: Tape feeder 3A to be mounted on component mounter 9 and tape feeder 3A retrieved from component mounter 9 are separately stored. The retrieval of tape feeder 3A may be performed by line conveyance device 9C and magazine conveyance vehicle 88, and may be performed by the worker. As a specific method of sorting and storing, there is a method of dividing storage section 21. For example, the storage positions of tape feeders 3A to be mounted are set to storage sections 21 in the third and fourth stages from the bottom, and the storage position of retrieved tape feeder 3A is set to storage section 21 in the first stage from the bottom.

Second storage mode: Tape feeder 3A to which reel RL is attached and tape feeder 3A to which reel RL is not attached are separately stored.

Third storage mode: Tape feeder 3A requiring maintenance and tape feeder 3A not requiring maintenance are separately stored.

Fourth storage mode: The storage position is determined based on the usage order of multiple tape feeders 3A indicated in production plan 9G of board K. For example, according to the usage order of multiple tape feeders 3A, tape feeders 3A are subsequently arranged and stored from a rightmost storage position to a storage position in a left direction. According to this, since tape feeders 3A need only to be unloaded in order from the rightmost storage position in the left direction, an unloading operation is made efficient, and risk of unloading errors is reduced.

Fifth storage mode: Multiple tape feeders 3A that are used for each type of board K indicated in production plan 9G are collectively stored in a storage area including multiple storage positions adjacent to each other. For example, one storage section 21 can be used as the storage area.

Sixth storage mode: Tape feeder 3A having an early recommended time of maintenance is preferentially stored at a storage position close to feeder maintenance device 3. For example, tape feeder 3A having an early recommended time of maintenance is preferentially stored at a storage position of storage section 21 in the first row from the left in the first stage or the third stage from the bottom. Further, tape feeder 3A for which the recommended time of maintenance has already passed or tape feeder 3A for which the recommended time of maintenance is earliest is stored at a leftmost storage position of storage section 21. Then, tape feeders 3A are arranged in the storage positions in a right direction in ascending order of the recommended time of maintenance and stored. According to this, the conveyance distance of tape feeder 3A for performing maintenance can be shortened, and an error in the order of performing maintenance is suppressed. As tape feeder 3A having the early recommended time of maintenance, for example, tape feeder 3A in which the recommended time is predicted to arrive during use of the carrier tape when new reel RL is attached can be exemplified. As tape feeder 3A in which the recommended time of maintenance has already passed, tape feeder 3A in which the carrier tape is used up after the recommended time arrives during the use of the carrier tape can be exemplified.

By selecting, for example, the first, second, and fifth storage modes, control device 7 can collectively store multiple tape feeders 3A to which reel RL is attached and which are to be mounted on component mounter 9 in one storage section 21. According to this, when multiple tape feeders 3A of pallet table 931 are exchanged, since tape feeders 3A collected in one storage section 21 need only to be unloaded and conveyed, the changeover is made efficient and the conveyance error is suppressed.

In addition, by selecting, for example, the second and sixth storage modes, control device 7 stores first tape feeder 3A, which has an early recommended time of maintenance and can perform maintenance immediately after reel RL is detached, close to feeder maintenance device 3. In addition, control device 7 stores second tape feeder 3A, to which reel RL is attached and which cannot immediately perform maintenance even when the recommended time for maintenance is early, close to reel attachment/detachment device 4. According to this, an operation of inserting first tape feeder 3A into feeder maintenance device 3 to perform maintenance and an operation of inserting second tape feeder 3A into reel attachment/detachment device 4 to detach reel RL can be made efficient. That is, by storing tape feeder 3A at the storage position close to a next conveyance destination (insertion destination) which changes according to the current state of tape feeder 3A, control device 7 can shorten the subsequent conveyance distance and improve efficiency.

Control device 7 may adopt a mode other than the above-described six storage modes. For example, in feeder storage system 1 provided in common to multiple board work line 9A, control device 7 can assign three storage sections 21 and one storage section 22 for each row of storage 2 to first to fourth board work lines 9A, respectively. Further, similarly to tape feeder 3A, control device 7 can apply at least one storage mode described above to nozzle feeder 5A as a target and determine the storage position. Control device 7 applies, for example, the first, second, and fifth storage modes to nozzle feeder 5A as a target. That is, control device 7 stores nozzle feeder 5A that is used for the changeover in same storage section 21 as tape feeder 3A that is used for the same changeover, and can efficiently address the changeover. Control device 7 applies, for example, the second and sixth storage modes to nozzle feeder 5A as a target. That is, control device 7 stores first nozzle feeder 5A that performs maintenance and storage of suction nozzle 95, close to nozzle operation device 5, and stores second nozzle feeder 5A that maintains a current state in preparation for the future use schedule, away from nozzle operation device 5.

Control device 7 further includes functions of first command section 71, second command section 72, third command section 73, fourth command section 74, and fifth command section 75 that are in charge of loading/unloading control and the like of storage 2. First command section 71 performs control based on the tape setup command for attaching reel RL to tape feeder 3A and performing setup. The tape setup command includes combination information that defines a combination of the type of tape feeder 3A and the type of the component supplied by reel RL. First command section 71 inquires of management device 70 whether tape feeder 3A to which reel RL conforming to the combination information has been attached (the setup has been completed) is stored in storage 2.

When tape feeders 3A for which the setup has been completed are stored in storage 2, first command section 71 does nothing. When tape feeder 3A is not stored, first command section 71 inquires of management device 70 whether tape feeder 3A (to which reel RL is not attached) which is a use candidate conforming to the combination information is stored in storage 2. When tape feeder 3A is stored, first command section 71 commands conveyance device 6 to move along the arrangement direction and convey tape feeder 3A from storage 2 to reel attachment/detachment device 4. In addition, when the tape feeders which are use candidates are not stored in storage 2, first command section 71 commands feeder conveyance robot 84 to convey tape feeders 3A which are use candidates from equipment warehouse 85 to reel attachment/detachment device 4.

Here, the combination information defines the type of tape feeder 3A and does not define individual tape feeder 3A. Therefore, multiple tape feeders 3A which are use candidates may be stored in storage 2, or multiple tape feeders 3A which are use candidates may be stored in equipment warehouse 85. In this case, first command section 71 selects tape feeder 3A to be used (to be conveyed to reel attachment/detachment device 4) based on the operation history of each of multiple tape feeders 3A. For example, first command section 71 selects tape feeder 3A having a low error rate indicated in equipment history data 9J or tape feeder 3A having a late recommended time of the next maintenance.

Next, first command section 71 commands reel conveyance vehicle 86 to convey reel RL which is a use candidate conforming to the combination information from component warehouse 87 to reel attachment/detachment device 4. Here, the combination information defines the type of the component supplied by reel RL and does not define individual reel RL. Therefore, multiple reels RL which are use candidates may be stored in component warehouse 87. In this case, first command section 71 selects reel RL to be used based on the use history of each of multiple reels RL. For example, first command section 71 selects reel RL in which a production time or a use start time indicated by component history data 9K is old or reel RL in which the remaining number of components is small. Alternatively, first command section 71 selects reel RL having the remaining number of components corresponding to the required quantity required for the components.

Further, first command section 71 commands reel attachment/detachment device 4 to attach conveyed reel RL to conveyed tape feeder 3A. Reel attachment/detachment device 4 attaches reel RL to tape feeder 3A according to the command. Thereafter, the first command section 71 commands conveyance device 6 to convey and store tape feeder 3A for which the setup has been completed from reel attachment/detachment device 4 to storage 2. Conveyance device 6 conveys tape feeder 3A and loads tape feeder 3A into storage 2 according to the command. By the above operation, the setup of tape feeder 3A is ended.

First command section 71 sets tape feeder 3A retrieved from component mounter 9 as a storage target. Tape feeder 3A as a storage target is accommodated in feeder magazine 81, and feeder magazine 81 is stored in storage section 22 by magazine conveyance vehicle 88. Based on production plan 9G, first command section 71 determines whether to store retrieved tape feeder 3A at the storage position of storage 2 or convey tape feeder 3A to reel attachment/detachment device 4 to detach reel RL. Specifically, first command section 71 determines to store tape feeder 3A in storage 2 while maintaining the current state of tape feeder 3A with the future use schedule indicated in production plan 9G, and commands conveyance device 6 to perform the storage.

In addition, first command section 71 determines to convey tape feeder 3A without the future use schedule in production plan 9G and tape feeder 3A to which used reel RL is attached to reel attachment/detachment device 4, and commands conveyance device 6 to perform the conveyance. Further, first command section 71 commands reel attachment/detachment device 4 to detach reel RL from conveyed tape feeder 3A. Thereafter, first command section 71 determines whether tape feeder 3A as a target from which reel RL is detached is a use candidate in the next board type and the subsequent board types in production plan 9G. When tape feeder 3A is a use candidate, first command section 71 commands conveyance device 6 to convey and load tape feeder 3A from reel attachment/detachment device 4 to storage 2. When tape feeder 3A is not a use candidate, first command section 71 commands feeder conveyance robot 84 to convey and load tape feeder 3A from reel attachment/detachment device 4 to equipment warehouse 85.

Second command section 72 operates according to the changeover command for preparing multiple tape feeders 3A used for production of the next board type or the subsequent board types of board K indicated in production plan 9G. Prior to the command of second command section 72, the setup of multiple tape feeders 3A to be used and the storage in storage 2 are performed in advance by first command section 71. Second command section 72 commands conveyance device 6 to collectively accommodate multiple tape feeders 3A in feeder magazine 81 stored in storage section 22. When the quantity of tape feeders 3A used for the changeover is large and exceeds the accommodation capacity of feeder magazine 81, second command section 72 can designate multiple feeder magazines 81.

Here, tape feeders 3A which are use candidates more than the required number indicated in production plan 9G may be stored in storage section 21. In this case, second command section 72 selects the required number of tape feeders 3A to be accommodated in feeder magazine 81 based on the operation history of each of a large number of tape feeders 3A or the use history of reel RL attached to each of tape feeders 3A. For example, second command section 72 selects tape feeder 3A having a low error rate indicated in equipment history data 9J, or selects tape feeder 3A to which reel RL having an old production time of the component indicated in component history data 9K is attached. Further, second command section 72 commands magazine conveyance vehicle 88 to convey feeder magazine 81 in which multiple tape feeders 3A have been accommodated to buffer station 9B of board work line 9A.

Third command section 73 operates according to the changeover command for preparing the changeover of multiple tape feeders 3A and nozzle feeders 5A used for the production of the next board type and the subsequent board types of board K. Third command section 73 commands nozzle operation device 5 to cause nozzle feeder 5A to hold multiple suction nozzles 95 which are used for each type of board K indicated in production plan 9G. Nozzle operation device 5 causes nozzle station 5C to hold multiple suction nozzles 95 according to the command, and further attaches nozzle station 5C to nozzle feeder 5A. Alternatively, nozzle operation device 5 causes nozzle station 5C attached to nozzle feeder 5A to hold multiple suction nozzles 95 according to the command. Thus, the setup of nozzle feeder 5A is ended.

Third command section 73 commands conveyance device 6 to collectively store multiple tape feeders 3A and nozzle feeders 5A to be used in the storage area including the multiple storage positions adjacent to each other. For example, one storage section 21 can be used as the storage area. Third command section 73 may assign separate storage areas, that is, separate storage sections 21 to two component mounters 9 constituting board work line 9A.

Fourth command section 74 operates for nozzle feeder 5A as a target which is retrieved to storage section 22 by feeder magazine 81. Fourth command section 74 commands handling of nozzle feeder 5A retrieved from component mounter 9 based on at least one of production plan 9G of board K and the operation history of suction nozzle 95. That is, fourth command section 74 determines and commands whether to store nozzle feeder 5A in storage 2 by means of conveyance device 6 or convey nozzle feeder 5A to equipment warehouse 85 by means of conveyance device 6 and feeder conveyance robot 84.

For example, when there is a future use schedule of nozzle feeder 5A in production plan 9G, fourth command section 74 commands conveyance device 6 to store nozzle feeder 5A in storage 2 while maintaining the current state of nozzle feeder 5A. Meanwhile, when there is no future use schedule of nozzle feeder 5A, fourth command section 74 commands feeder conveyance robot 84 to convey nozzle feeder 5A to equipment warehouse 85. Further, fourth command section 74 may command conveyance device 6 to convey nozzle feeder 5A to nozzle operation device 5, and may command nozzle operation device 5 to detach nozzle station 5C or suction nozzle 95 from nozzle feeder 5A and store nozzle station 5C or suction nozzle 95. Note that feeder holding section 52 of nozzle operation device 5 can also be used as the storage position. In addition, when the recommended time of maintenance of suction nozzle 95 held by nozzle feeder 5A is close or has already passed, fourth command section 74 commands conveyance device 6 to convey nozzle feeder 5A to nozzle operation device 5, and commands nozzle operation device 5 to perform maintenance of suction nozzle 95.

Fifth command section 75 commands conveyance device 6 to collectively accommodate multiple tape feeders 3A and nozzle feeders 5A in feeder magazine 81 stored in storage section 22. Prior to the operation of fifth command section 75, the setup of multiple tape feeders 3A and the storage in storage 2 are performed in advance by first command section 71, and the setup of nozzle feeder 5A and the storage in storage 2 are performed in advance by third command section 73. Fifth command section 75 commands magazine conveyance vehicle 88 to convey feeder magazine 81 in which tape feeder 3A and nozzle feeder 5A have been accommodated to buffer station 9B of board work line 9A. The functions of first to fifth command sections 71 to 75 will be described in the operation described below.

### 8. Operation of Feeder Storage System 1

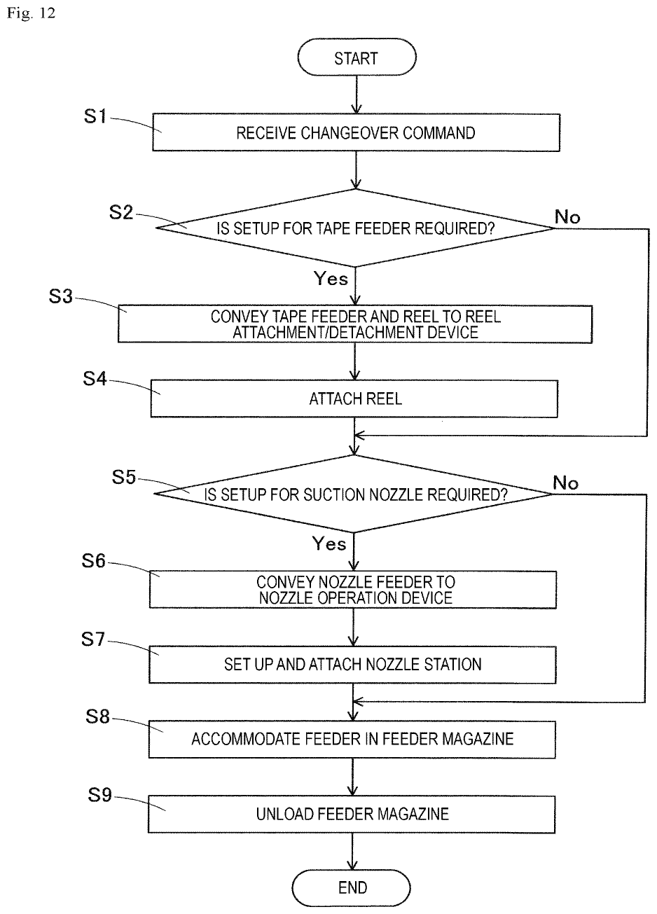

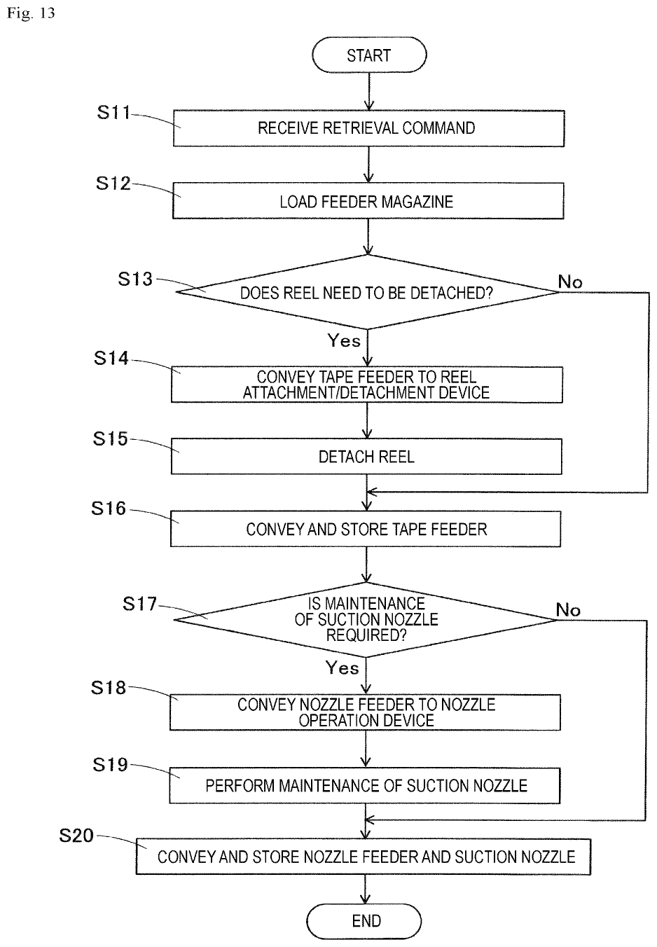

Next, the operation of feeder storage system 1 will be described by taking a case where the changeover command is received (refer to FIG. 12) and a case where the retrieval command is received (refer to FIG. 13) as examples. As the mounting work of component mounter 9 progresses, production management device 9E transmits the changeover command in a timely manner. In step S1 of an operation flow of FIG. 12, control device 7 receives the changeover command. As described above, the changeover command includes the tape setup command and the conveyance command, and includes or does not include the nozzle setup command depending on cases.

In next step S2, first command section 71 of control device 7 determines whether the setup for attaching reel RL to tape feeder 3A is required based on the combination information of tape feeder 3A and reel RL indicated in the tape setup command. When all tape feeders 3A conforming to respective pieces of the combination information indicated by multiple tape setup commands are stored in storage 2, the setup is not required. In this case, first command section 71 advances the operation flow to step S5.

In step S3 when the setup is required, first command section 71 commands conveyance device 6 to convey tape feeder 3A (reel RL is not attached) conforming to the combination information from storage 2 to reel attachment/detachment device 4. Alternatively, first command section 71 commands feeder conveyance robot 84 to convey tape feeder 3A conforming to the combination information from equipment warehouse 85 to reel attachment/detachment device 4. Conveyance device 6 or feeder conveyance robot 84 conveys tape feeder 3A to reel attachment/detachment device 4 according to the command, and inserts tape feeder 3A into feeder holding section 44 through feeder insertion opening 414.

In addition, first command section 71 commands reel conveyance vehicle 86 to convey reel RL conforming to the combination information from component warehouse 87 to reel attachment/detachment device 4. When the setup of multiple tape feeders 3A is performed, first command section 71 commands reel conveyance vehicle 86 to collectively convey multiple reels RL using reel holding body 421. Reel conveyance vehicle 86 conveys single reel RL or reel holding body 421 holding multiple reels RL to reel attachment/detachment device 4 according to the command, loads reel holding body 421 through reel loading opening 413, and places reel holding body 421 on reel loading table 42. The command of first command section 71 is also transmitted to the warehouse control section of equipment warehouse 85 and the warehouse control section of component warehouse 87, and tape feeder 3A, reel RL, and reel holding body 421 are unloaded without error and without delay.

In next step S4, first command section 71 commands reel attachment/detachment device 4 to attach conveyed reel RL to conveyed tape feeder 3A. Reel attachment/detachment device 4 attaches reel RL to tape feeder 3A according to the command. Further, first command section 71 commands conveyance device 6 to convey and load tape feeder 3A for which the setup has been completed from reel attachment/detachment device 4 to storage 2. Conveyance device 6 conveys tape feeder 3A according to the command and stores tape feeder 3A in storage 2. When the setup of multiple tape feeders 3A is performed, first command section 71 repeatedly executes step S3 and step S4, and issues a command to collectively store multiple tape feeders 3A for which the setup has been completed in same storage section 21 of storage 2. Alternatively, first command section 71 assigns different storage sections 21 to two component mounters 9, respectively, and issues a command to collectively store multiple tape feeders 3A.

In next step S5, third command section 73 determines whether the setup for suction nozzle 95 is required. When the changeover command does not include the nozzle setup command and when nozzle feeder 5A conforming to the nozzle setup command included in the changeover command is stored in storage 2, the setup is not required. In this case, third command section 73 advances the operation flow to step S8. In step S6 when the setup is required, third command section 73 commands conveyance device 6 to convey nozzle feeder 5A from storage 2 to nozzle operation device 5. Alternatively, first command section 71 commands feeder conveyance robot 84 to convey nozzle feeder 5A from equipment warehouse 85 to reel attachment/detachment device 4. Conveyance device 6 or feeder conveyance robot 84 conveys nozzle feeder 5A according to the command and inserts nozzle feeder 5A into feeder holding section 52 of nozzle operation device 5. When usable nozzle feeder 5A is stored in feeder holding section 52, step S6 is omitted.

In next step S7, third command section 73 commands nozzle operation device 5 to cause nozzle feeder 5A to hold multiple suction nozzles 95 indicated by the nozzle setup command. Nozzle operation device 5 causes nozzle station 5C to hold multiple suction nozzles 95 according to the command. Subsequently, nozzle operation device 5 performs the setup work for attaching nozzle station 5C for which the setup has been completed to nozzle feeder 5A. Alternatively, nozzle operation device 5 performs setup work for causing nozzle station 5C attached to nozzle feeder 5A to hold suction nozzles 95 one by one. Further, third command section 73 commands conveyance device 6 to convey nozzle feeder 5A for which the setup has been completed from nozzle operation device 5 to storage 2 and load nozzle feeder 5A into storage section 21 in which tape feeder 3A is stored in step S4. Conveyance device 6 conveys nozzle feeder 5A according to the command and loads nozzle feeder 5A into same storage section 21 as tape feeder 3A for which the setup has been completed.

In next step S8, second command section 72 operates when the nozzle setup command is not included in the changeover command, and fifth command section 75 operates when the nozzle setup command is included in the changeover command. Specifically, second command section 72 commands conveyance device 6 to collectively accommodate multiple tape feeders 3A stored in storage section 21 in feeder magazine 81 stored in storage section 22. Alternatively, fifth command section 75 commands conveyance device 6 to collectively accommodate multiple tape feeders 3A and nozzle feeders 5A stored in storage section 21 in feeder magazine 81 stored in storage section 22. Conveyance device 6 accommodates multiple tape feeders 3A in feeder magazine 81 according to the command, and accommodates nozzle feeder 5A also in feeder magazine 81 when nozzle feeder 5A is stored in storage section 21. When the quantity of tape feeders 3A and nozzle feeders 5A exceeds the accommodation capacity of feeder magazine 81, second command section 72 or fifth command section 75 designates multiple feeder magazines 81.

In next Step S9, second command section 72 or fifth command section 75 commands magazine conveyance vehicle 88 to convey feeder magazine 81 to buffer station 9B of board work line 9A. Thereafter, magazine conveyance vehicle 88 unloads feeder magazine 81 from storage 2 according to the command, conveys feeder magazine 81 to buffer station 9B, and repeats the conveyance work by the quantity of feeder magazines 81. As a result, feeder storage system 1 ends the preparation for the changeover and the operation flow is ended.

Line conveyance device 9C conveys multiple tape feeders 3A and nozzle feeders 5A from feeder magazine 81 of buffer station 9B to pallet table 931 of component mounter 9 and performs the changeover, when the time for the changeover arrives. Line conveyance device 9C inserts multiple tape feeders 3A and nozzle feeders 5A detached from component mounter 9 in the changeover into feeder magazine 81 of buffer station 9B. After the changeover is ended, production management device 9E transmits the retrieval command in a timely manner. Accordingly, feeder storage system 1 starts the operation flow shown in FIG. 13. In step S11, control device 7 receives the retrieval command. As described above, the retrieval command includes the conveyance command and the storage command, and includes or does not include the maintenance command depending on cases.

In next step S12, magazine conveyance vehicle 88 conveys and loads feeder magazine 81 loaded in buffer station 9B into storage 2, and accommodates feeder magazine 81 in storage section 22. In next step S13, first command section 71 determines whether reel RL needs to be detached from retrieved tape feeder 3A. It is advantageous to store tape feeder 3A with the future use schedule or tape feeder 3A having high versatility of a component to be supplied even if the use schedule is not determined in a state in which reel RL is attached. When all of retrieved tape feeders 3A correspond to the above, the detachment is not required. In this case, first command section 71 advances the operation flow to step S16.

Meanwhile, in tape feeder 3A without the future use schedule or tape feeder 3A to which used reel RL is attached, it is advantageous to detach reel RL. When one or more of retrieved tape feeders 3A correspond to the above, the detachment is required. In step S14 in this case, first command section 71 commands conveyance device 6 to convey tape feeder 3A in feeder magazine 81 of storage section 22 to reel attachment/detachment device 4. Conveyance device 6 conveys tape feeder 3A to reel attachment/detachment device 4 according to the command, and inserts tape feeder 3A into feeder holding section 44 through feeder insertion opening 414.

In next step S15, first command section 71 commands reel attachment/detachment device 4 to detach reel RL from conveyed tape feeder 3A. Reel attachment/detachment device 4 detaches reel RL from tape feeder 3A according to the command. In step S16 following step S15, first command section 71 commands conveyance device 6 or feeder conveyance robot 84 to convey and store tape feeder 3A from which reel RL is detached. In step S16 following step S13, first command section 71 commands conveyance device 6 to convey and store tape feeder 3A to which reel RL is attached. Conveyance device 6 conveys tape feeder 3A according to the command and stores tape feeder 3A in storage 2. Alternatively, feeder conveyance robot 84 conveys tape feeder 3A according to the command and stores tape feeder 3A in equipment warehouse 85.

In next step S17, fourth command section 74 determines whether maintenance of suction nozzle 95 held by retrieved nozzle feeder 5A is required. Fourth command section 74 can appropriately determine whether maintenance is required based on the recommended time of maintenance indicated by equipment history data 9J. When the maintenance is not required, fourth command section 74 advances the operation flow to step S20. In step S18 when maintenance is required, fourth command section 74 commands conveyance device 6 to convey nozzle feeder 5A in feeder magazine 81 of storage section 22 to nozzle operation device 5. Conveyance device 6 conveys nozzle feeder 5A to nozzle operation device 5 according to the command, and inserts nozzle feeder 5A into feeder holding section 52.

In next step S19, fourth command section 74 causes nozzle operation device 5 to perform maintenance of suction nozzle 95. In step S20 following step S19, fourth command section 74 issues a command to convey and store nozzle feeder 5A and suction nozzle 95. Based on production plan 9G of board K, fourth command section 74 determines a storage place of nozzle feeder 5A to be one of storage section 21 of storage 2, equipment warehouse 85, and feeder holding section 52 of nozzle operation device 5. Meanwhile, storage places of suction nozzle 95 and nozzle station 5C are storage unit 56 of nozzle operation device 5. Note that nozzle feeder 5A may be stored in a state of holding again suction nozzle 95 that has been detached once and subjected to maintenance.

In step S20 following step S17, fourth command section 74 issues a command to convey and store nozzle feeder 5A in a state of holding suction nozzle 95. Nozzle feeder 5A is conveyed and stored by conveyance device 6 or feeder conveyance robot 84. When nozzle feeder 5A is not retrieved from component mounter 9, steps S17 to S20 are omitted. As a result, in feeder storage system 1, the retrieval and storage after the changeover are ended, and the operation flow is ended.

Feeder storage system 1 can repeat the operation flow of FIG. 12 when two changeover commands of which changeover execution times are close to each other are received simultaneously or received successively in board work line 9A. In addition, feeder storage system 1 can repeat the operation flow of FIG. 12 when different changeover commands are received simultaneously or received successively from two board work lines 9A. Further, feeder storage system 1 may operate by receiving a command other than the changeover command or the retrieval command. For example, feeder storage system 1 addresses component shortage of tape feeder 3A which occurs with the progress of the mounting work of component mounter 9. That is, feeder storage system 1 can set up one or more tape feeders 3A having a limited quantity and convey tape feeders 3A to buffer station 9B.

Feeder storage system 1 addresses a case where an occurrence frequency of the operation error becomes excessive in specific tape feeder 3A or specific suction nozzle 95 during the operation of component mounter 9. That is, feeder storage system 1 can set up tape feeders 3A having a limited quantity or nozzle feeders 5A having a limited quantity which hold suction nozzles 95 and convey tape feeders 3A or nozzle feeders 5A to buffer station 9B. Further, feeder storage system 1 can perform reuse in which reel RL of tape feeder 3A retrieved from component mounter 9 is exchanged with new reel RL by reel attachment/detachment device 4 and is immediately returned to component mounter 9. In addition, feeder storage system 1 can perform reuse in which suction nozzle 95 of nozzle feeder 5A retrieved from component mounter 9 is exchanged with new suction nozzle 95 by nozzle operation device 5 and is immediately returned to component mounter 9.

In feeder storage system 1 of the embodiment, conveyance device 6 conveys tape feeder 3A between storage 2 and feeder maintenance device 3. According to this, it is possible to save labor in the work of conveying tape feeder 3A between storage 2 and feeder maintenance device 3 and the work of taking tape feeder 3A into and out of storage 2 or feeder maintenance device 3 as compared with the conventional art.

### 9. Applications and Modifications of Embodiment

Second conveyance device (feeder conveyance robot 84 and reel conveyance vehicle 86) and the member warehouse (equipment warehouse 85 and component warehouse 87) can be variously modified. For example, the articulated arm type robot, which is one form of feeder conveyance robot 84, may convey reel RL using equipment warehouse 85 as a component warehouse, or the automated guided vehicle, which is one form of reel conveyance vehicle 86, may convey tape feeder 3A and nozzle feeder 5A using component warehouse 87 as an equipment warehouse. Further, the second conveyance device (feeder conveyance robot 84 and reel conveyance vehicle 86) may also be used for conveying other members. In addition, tape feeder 3A, nozzle feeder 5A, reel RL, and the like (equipment and components) can be configured to be stored in an integrated manner with the member warehouse as one location, or the conveyance distance can be shortened with the member warehouse as three or more locations.

In addition, feeder storage system 1 of the embodiment can be simplified by appropriately omitting the elements. For example, nozzle operation device 5, third command section 73, and fifth command section 75 can be omitted by excluding nozzle feeder 5A that supplies suction nozzle 95 from a target. Further, some or all of feeder conveyance robot 84, reel conveyance vehicle 86, and magazine conveyance vehicle 88 may be omitted, and the conveyance work performed by these may be performed by the worker.

Further, a feeder storage system of a first simple embodiment, which is largely omitted, includes three elements of storage 2, feeder maintenance device 3, and conveyance device 6. Then, tape feeder 3A is loaded into storage 2 by the worker. Even in this case, conveyance device 6 can select tape feeder 3A in which the recommended time of maintenance is close or tape feeder 3A in which the recommended time of maintenance has passed and automatically convey tape feeder 3A to feeder maintenance device 3. Therefore, it is possible to save labor in the work of conveying tape feeder 3A between storage 2 and feeder maintenance device 3 and the work of taking tape feeder 3A into and out of storage 2 or feeder maintenance device 3.

Further, a feeder storage system of a second simple embodiment includes three elements of storage 2, reel attachment/detachment device 4, and conveyance device 6. The worker performs the work of loading and unloading tape feeder 3A and reel RL into and out of reel attachment/detachment device 4 with respect to a member warehouse. Even in this case, conveyance device 6 can automatically convey tape feeder 3A to which reel RL is attached and which is set up from reel attachment/detachment device 4 to storage 2, and can automatically convey tape feeder 3A as a target from which reel RL is to be detached from storage 2 to reel attachment/detachment device 4. Therefore, it is possible to save labor in the work of conveying tape feeder 3A between storage 2 and reel attachment/detachment device 4 and the work of taking tape feeder 3A into and out of storage 2 or reel attachment/detachment device 4. Other various applications and modifications can also be made to the embodiment.

### REFERENCE SIGNS LIST

1: feeder storage system, 2: storage, 21: storage section, 22: storage section, 3: feeder maintenance device, 3A: tape feeder, 4: reel attachment/detachment device, 421: reel holding body, 5: nozzle operation device, 5A: nozzle feeder, 5C: nozzle station, 6: conveyance device, 7: control device, 70: management device, 71: first command section, 72: second command section, 73: third command section, 74: fourth command section, 75: fifth command section, 81: feeder magazine, 84: feeder conveyance robot, 85: equipment warehouse, 86: reel conveyance vehicle, 87: component warehouse, 88: magazine conveyance vehicle, 9: component mounter, 95: suction nozzle, 9A: board work line, 9D: line management device, 9E: production management device, 9G: production plan, 9H: mounting work data, 9J: equipment history data, 9K: component history data, K: board, RL: reel

1. (canceled)

2. A feeder storage system comprising:
a storage configured to store a tape feeder that is detachably mounted on a component mounter and supplies a component;
a feeder maintenance device disposed adjacent to the storage and configured to perform maintenance of the tape feeder; and
a conveyance device configured to move along an arrangement direction of the storage and the feeder maintenance device and convey the tape feeder between the storage and the feeder maintenance device,
wherein the storage includes plurality of storage sections configured to accommodate the tape feeder in a vertical direction.

3. The feeder storage system according to claim 2, further comprising:
a reel attachment/detachment device disposed adjacent to the storage and configured to attach and detach a reel, around which a carrier tape that holds the component is wound, to and from the tape feeder;
wherein the conveyance device is configured to move along a arrangement direction of the storage and the reel attachment/detachment device and convey the tape feeder between the storage and the reel attachment/detachment device.

4. The feeder storage system according to claim 3, further comprising:
a second conveyance device configured to convey at least one of the tape feeder and the reel between the reel attachment/detachment device and a member warehouse.

5. The feeder storage system according to claim 4, further comprising:
a third conveyance device configured to convey the tape feeder between the component mounter or a board work line including the component mounter and the storage.

6. The feeder storage system according to claim 5,
wherein the third conveyance device is configured to convey a feeder magazine configured to accommodate multiple tape feeders,
the storage is configured to store the feeder magazine, and
the conveyance device is configured to perform insertion and removal operation of the tape feeder into and from the feeder magazine stored in the storage.

7. The feeder storage system according to claim 2,
wherein the storage is configured to store a mounting tool feeder that is configured to exchangeably hold a component mounting tool, which is detachably mounted on the component mounter and mounts the component collected from the tape feeder on a board, the mounting tool feeder having a storage position compatible with that of the tape feeder.

8. The feeder storage system according to claim 7, further comprising:
a mounting tool operation device disposed adjacent to the storage and configured to perform at least one of storing, maintaining, and an attaching/detaching to and from the mounting tool feeder, for the component mounting tool,
wherein the conveyance device is configured to move along an arrangement direction of the storage and the mounting tool operation device and convey the mounting tool feeder between the storage and the mounting tool operation device,
wherein the mounting tool feeder is configured to attachably and detachably hold a mounting tool station that exchangeably holds multiple component mounting tools, and
the mounting tool operation device is configured to store the mounting tool station.

9. (canceled)

10. The feeder storage system according to claim 7, further comprising:
a second conveyance device configured to convey the mounting tool feeder between the storage and a member warehouse.

11. The feeder storage system according to claim 7, further comprising:
a third conveyance device configured to convey the tape feeder and the mounting tool feeder between the component mounter or a board work line including the component mounter and the storage,
wherein the third conveyance device is configured to convey a feeder magazine configured to accommodate multiple combinations of the tape feeder and the mounting tool feeder,
the storage is configured to store the feeder magazine, and
the conveyance device is configured to perform insertion and removal operation of the tape feeder and the mounting tool feeder into and from the feeder magazine stored in the storage.

12. (canceled)

13. The feeder storage system according to claim 2, further comprising:
a management device configured to manage a storage situation of the tape feeder stored in the storage; and
a control device configured to determine a storage position of multiple tape feeders inside the storage and control the conveyance device and the feeder maintenance device based on storage status information from the management device.

14. The feeder storage system according to claim 13,
wherein the control device is configured to select and control at least one storage mode of
a first storage mode in which the tape feeder to be mounted on the component mounter and the tape feeder retrieved from the component mounter are separately stored,
a second storage mode in which the tape feeder to which a reel, around which a carrier tape that holds the component is wound, is attached and the tape feeder to which the reel is not attached are separately stored, and
a third storage mode in which the tape feeder requiring the maintenance and the tape feeder not requiring the maintenance are separately stored.

15. The feeder storage system according to claim 14,
wherein the control device is configured to further select at least one storage mode of
a fourth storage mode in which the storage position is determined based on a usage order of the multiple tape feeders indicated in a production plan of a board on which the component is mounted,
a fifth storage mode in which the multiple tape feeders that are used for each board type indicated in the production plan are collectively stored in a storage area including multiple storage positions adjacent to each other, and
a sixth storage mode in which the tape feeder having an early recommended maintenance timing set based on an operation history of the tape feeder is preferentially stored at the storage position adjacent to the feeder maintenance device.

16. (canceled)

17. The feeder storage system according to claim 13, further comprising:
a reel attachment/detachment device disposed adjacent to the storage and configured to attach and detach a reel, around which a carrier tape that holds the component is wound, to and from the tape feeder; and
a second conveyance device configured to convey at least one of the tape feeder and the reel between the reel attachment/detachment device and a member warehouse,
wherein the control device includes a first command section configured to command the conveyance device to move along an arrangement direction of the storage and the reel attachment/detachment device and convey the tape feeder between the storage and the reel attachment/detachment device, command the second conveyance device to convey, when the tape feeder, to which the reel conforming to combination information that is included in a production plan of a board on which the component is mounted and that defines a combination of the tape feeder and the reel has been attached, is not stored in the storage, at least one of the tape feeder and the reel conforming to the combination information from the member warehouse to the reel attachment/detachment device, and command the reel attachment/detachment device to attach the reel to the tape feeder.

18. The feeder storage system according to claim 17,
wherein the first command section is configured to select, when there are the multiple tape feeders or multiple reels which are use candidates conforming to the combination information, the tape feeder to be used or the reel to be used based on an operation history of each of the multiple tape feeders or a use history of each of the multiple reels.

19. The feeder storage system according to claim 17,
wherein the first command section is configured to determine whether to store the tape feeder retrieved from the component mounter as a target at the storage position or convey the tape feeder to the reel attachment/detachment device to detach the reel, based on the production plan.

20. The feeder storage system according to claim 13, further comprising:
a third conveyance device configured to convey a feeder magazine that is configured to accommodate the multiple tape feeders between the component mounter or a board work line including the component mounter and the storage,
wherein the storage is configured to store the feeder magazine,
the conveyance device is configured to perform insertion and removal operation of the tape feeder into and from the feeder magazine stored in the storage,
the control device includes a second command section configured to command the conveyance device to collectively accommodate, in the feeder magazine stored in the storage, the multiple tape feeders that are used for each board type, on which the component is mounted, indicated in a production plan of the board, and command the third conveyance device to convey the feeder magazine in which the multiple tape feeders have been accommodated to the component mounter or the board work line, and
the second command section is configured to select, when a large number of the tape feeders that are use candidates are stored in the storage, the number being larger than a required number indicated in the production plan, the required number of the tape feeders to be accommodated in the feeder magazine based on an operation history of each of the large number of tape feeders or a use history of a reel around which a carrier tape that holds the component is wound and which is attached to each of the large number of tape feeders.

21. (canceled)

22. The feeder storage system according to claim 13, further comprising:
a mounting tool operation device disposed adjacent to the storage and configured to perform at least one of storage, maintenance, and an attachment/detachment operation to and from a mounting tool feeder, for a component mounting tool,
wherein the storage is configured to store the mounting tool feeder that exchangeably holds the component mounting tool that is detachably mounted on the component mounter and mounts the component collected from the tape feeder on a board, the mounting tool feeder having compatibility with the tape feeder in terms of the storage position,
the control device includes a third command section configured to command the conveyance device to collectively store, in a storage area including multiple storage positions adjacent to each other, the tape feeder and the mounting tool feeder that are used for each board type indicated in a production plan of the board,
the conveyance device is configured to move along an arrangement direction of the storage and the mounting tool operation device and convey the mounting tool feeder between the storage and the mounting tool operation device,
the third command section is configured to command the mounting tool operation device to hold, in the mounting tool feeder, multiple component mounting tools that are used for each board type, on which the component is mounted, indicated in the production plan of the board. and
the third command section is configured to determine whether to store the mounting tool feeder retrieved from the component mounter as a target at the storage position or convey the mounting tool feeder to the mounting tool operation device, based on at least one of the production plan and an operation history of the component mounting tool.

23-24. (canceled)

25. The feeder storage system according to claim 13,
wherein the storage is configured to store a mounting tool feeder that exchangeably holds a component mounting tool that is detachably mounted on the component mounter and mounts the component collected from the tape feeder on a board, the mounting tool feeder having compatibility with the tape feeder in terms of the storage position,
the feeder storage system further comprises:
a second conveyance device configured to convey the mounting tool feeder between the storage and a member warehouse, and
the control device includes a fourth command section configured to determine whether to store the mounting tool feeder retrieved from the component mounter at the storage position by means of the conveyance device or convey the mounting tool feeder to the member warehouse by means of the conveyance device and the second conveyance device, based on at least one of a production plan of the board on which the component is mounted and an operation history of the component mounting tool, to issue a command.

26. The feeder storage system according to claim 13,
wherein the storage is configured to store a mounting tool feeder that is configured to exchangeably hold a component mounting tool, which is detachably mounted on the component mounter and mounts the component collected from the tape feeder on a board, the mounting tool feeder having a storage position compatible with that of the tape feeder,
the feeder storage system further comprises:
a third conveyance device configured to convey a feeder magazine that is configured to accommodate multiple combinations of the tape feeder and the mounting tool feeder between the component mounter or a board work line including the component mounter and the storage,
the storage is configured to store the feeder magazine,
the conveyance device is configured to perform insertion and removal operations of the tape feeder and the mounting tool feeder into and from the feeder magazine stored in the storage, and
the control device includes a fifth command section configured to command the conveyance device to collectively accommodate, in the feeder magazine stored in the storage, the tape feeder and the mounting tool feeder that are used for each board type, on which the component is mounted, indicated in a production plan of the board, and command the third conveyance device to convey the feeder magazine in which the tape feeder and the mounting tool feeder have been accommodated to the component mounter or the board work line.
